(19) United States
(12) Patent Application Publication
(10) Pub. No.: US 2022/0293656 A1
(43) Pub. Date: Sep. 15, 2022

(54) SOLID-STATE IMAGING DEVICE AND ELECTRONIC APPARATUS

(71) Applicant: SONY SEMICONDUCTOR SOLUTIONS CORPORATION, KANAGAWA (JP)

(72) Inventor: SHINICHIRO KURIHARA, KANAGAWA (JP)

(21) Appl. No.: 17/638,674

(22) PCT Filed: Jul. 1, 2020
(86) PCT No.: PCT/JP2020/025782

§ 371 Date: Feb. 25, 2022

(30) Foreign Application Priority Data
Sep. 5, 2019 (JP) 2019-161866

(51) Int. Cl. H01L 27/146

(52) U.S. Cl. CPC H01L 27/14623; H01L 27/14621; H01L 27/14645; H01L 27/14625

(57) ABSTRACT

To provide a solid-state imaging device capable of preventing color mixing due to scattering of light. Provided is a solid-state imaging device including a plurality of pixels arranged therein, in which in each of the pixels, one on-chip lens that condenses incident light and at least one photoelectric converter formed in a semiconductor substrate are provided in order from a light incident side, at least one pixel among the plurality of pixels includes the one on-chip lens and the plurality of photoelectric converters, and between the plurality of photoelectric converters, a light absorbing member that absorbs at least a part of light condensed by the one on-chip lens is provided, or between the plurality of photoelectric converters, a light reflecting member that reflects at least a part of light condensed by the one on-chip lens is provided.

### TECHNICAL FIELD

The present technology relates to a solid-state imaging device and an electronic apparatus.

### BACKGROUND ART

In recent years, a digital camera has been more and more widely used, and a demand for a solid-state imaging device (image sensor), which is a main component for the digital camera, has been increased. Furthermore, in terms of performance of the solid-state imaging device, technological development for achieving high image quality and high functionality has been continued. For example, in order to avoid problems such as a decrease in sensitivity to incident light and a decrease in phase difference detection accuracy, a technique related to a solid-state imaging element on which a normal pixel that generates a pixel signal of an image and a phase difference detection pixel that generates a pixel signal used for calculation of a phase difference signal for controlling an image plane phase difference AF that is one AF function system are mix-mounted has been proposed (see Patent Document 1.).

### CITATION LIST

### Patent Document

Patent Document 1: WO 2016/098640 A

### SUMMARY OF THE INVENTION

### Problems to be Solved by the Invention

However, in the technique proposed in Patent Document 1, light is likely to be scattered near a portion between a plurality of photoelectric converters (photodiodes) (a central separation zone of a pixel, the central separation zone being a light condensing portion of an on-chip lens), and color mixing may increase due to scattered light.

Therefore, the present technology has been made in view of such a situation, and a main object thereof is to provide a solid-state imaging device capable of preventing color mixing due to scattering of light, and an electronic apparatus on which the solid-state imaging device is mounted.

### Solutions to Problems

The present inventor made intensive studies in order to solve the above-described object, and as a result, has succeeded in preventing color mixing, and has completed the present technology.

That is, the present technology provides, as a first aspect, a solid-state imaging device including a plurality of pixels arranged therein, in which in each of the pixels, one on-chip lens that condenses incident light and at least one photoelectric converter formed in a semiconductor substrate are provided in order from a light incident side, at least one pixel among the plurality of pixels includes the one on-chip lens and the plurality of photoelectric converters, and between the plurality of photoelectric converters, a light absorbing member that absorbs at least a part of light condensed by the one on-chip lens is provided.

In the solid-state imaging device according to the first aspect of the present technology, a moth-eye structure may be formed on a light receiving surface side of the semiconductor substrate above the photoelectric converter.

In the solid-state imaging device according to the first aspect of the present technology, a trench may be formed between the plurality of photoelectric converters, and the light absorbing member may be provided in at least a part of the trench.

In the solid-state imaging device according to the first aspect of the present technology, a trench may be formed between the plurality of photoelectric converters, and the light absorbing member and an insulating film may be provided in at least a part of the trench in order from a light incident side.

In the solid-state imaging device according to the first aspect of the present technology, a trench may be formed between the plurality of photoelectric converters, and a light absorbing member may be provided above the trench on a light incident side.

In the solid-state imaging device according to the first aspect of the present technology, the light absorbing member may contain at least one selected from the group consisting of tungsten (W), aluminum (Al), copper (Cu), and a carbon-based material.

In the solid-state imaging device according to the first aspect of the present technology, a trench may be formed between two of the pixels, and an insulating film may be provided in at least a part of the trench.

Furthermore, the present technology provides, as a second aspect,

a solid-state imaging device including a plurality of pixels arranged therein, in which

in each of the pixels, one on-chip lens that condenses incident light and at least one photoelectric converter formed in a semiconductor substrate are provided in order from a light incident side,

at least one pixel among the plurality of pixels includes the one on-chip lens and the plurality of photoelectric converters, and

between the plurality of photoelectric converters, a light reflecting member that reflects at least a part of light condensed by the one on-chip lens is provided.

In the solid-state imaging device according to the second aspect of the present technology,

a moth-eye structure may be formed on a light receiving surface side of the semiconductor substrate above the photoelectric converter.

In the solid-state imaging device according to the second aspect of the present technology,

a trench may be formed between the plurality of photoelectric converters, and a light reflecting member may be provided above the trench on a light incident side.

In the solid-state imaging device according to the second aspect of the present technology,

a trench may be formed between the plurality of photoelectric converters, and the light reflecting member may be provided in at least a part of the trench.

In the solid-state imaging device according to the second aspect of the present technology,

a trench may be formed between the plurality of photoelectric converters, and the light reflecting member and an insulating film may be provided in at least a part of the trench in order from a light incident side.

In the solid-state imaging device according to the second aspect of the present technology,

the light reflecting member may contain gold (Au) and/or silver (Ag).

In the solid-state imaging device according to the second aspect of the present technology,

a trench may be formed between two of the pixels, and an insulating film may be provided in at least a part of the trench.

Moreover, the present technology provides an electronic apparatus on which the solid-state imaging device according to the present technology is mounted.

The present technology can prevent color mixing due to scattering of light. Note that the effects described here are not necessarily limited, and may be any of the effects described in the present disclosure.

### BRIEF DESCRIPTION OF DRAWINGS

FIG. 1 is a diagram illustrating a configuration example of a solid-state imaging device according to a first embodiment to which the present technology is applied.

FIG. 2 is a diagram illustrating a configuration example of the solid-state imaging device according to the first embodiment to which the present technology is applied.

FIG. 3 is a diagram illustrating a configuration example of the solid-state imaging device according to the first embodiment to which the present technology is applied.

FIG. 4 is a diagram illustrating a configuration example of a solid-state imaging device according to a second embodiment to which the present technology is applied.

FIG. 5 is a diagram illustrating a configuration example of the solid-state imaging device according to the first embodiment to which the present technology is applied.

FIG. 6 is a diagram illustrating a configuration example of the solid-state imaging device according to the first embodiment to which the present technology is applied.

FIG. 7 is a diagram illustrating a configuration example of the solid-state imaging device according to the first embodiment to which the present technology is applied.

FIG. 8 is a diagram illustrating a configuration example of a solid-state imaging device according to a third embodiment to which the present technology is applied.

FIG. 9 is a diagram illustrating a configuration example of the solid-state imaging device according to the third embodiment to which the present technology is applied.

FIG. 10 is a diagram illustrating a configuration example of the solid-state imaging device according to the third embodiment to which the present technology is applied.

FIG. 11 is a diagram illustrating a configuration example of a solid-state imaging device according to a fourth embodiment to which the present technology is applied.

FIG. 12 is a diagram illustrating a configuration example of the solid-state imaging device according to the third embodiment to which the present technology is applied.

FIG. 13 is a diagram illustrating a configuration example of the solid-state imaging device according to the third embodiment to which the present technology is applied.

FIG. 14 is a diagram illustrating a configuration example of the solid-state imaging device according to the third embodiment to which the present technology is applied.

FIG. 15 is a diagram illustrating a use example of the solid-state imaging devices according to the first to fourth embodiments to which the present technology is applied.

FIG. 16 is a functional block diagram of an example of an electronic apparatus according to a fifth embodiment to which the present technology is applied.

FIG. 17 is a diagram illustrating an example of a schematic configuration of an endoscopic surgical system.

FIG. 18 is a block diagram illustrating examples of functional configurations of a camera head and a CCU.

FIG. 19 is a block diagram illustrating an example of a schematic configuration of a vehicle control system.

FIG. 20 is an explanatory diagram illustrating examples of installation positions of a vehicle external information detection unit and an imaging unit.

### MODE FOR CARRYING OUT THE INVENTION

Hereinafter, a preferable embodiment for carrying out the present technology will be described. The embodiments described below exemplify representative embodiments of the present technology, and the scope of the present technology is not narrowly interpreted by the embodiments. Note that, unless otherwise specified, in the drawings, “upper” means an upper direction or an upper side in the drawings, “lower” means a lower direction or a lower side in the drawings, “left” means a left direction or a left side in the drawings, and “right” means a right direction or a right side in the drawings. Furthermore, in the drawings, the same or equivalent elements or members are designated by the same reference numeral, and duplicate description will be omitted.

Description will be made in the following order.

1. Summary of the present technology

2. First Embodiment (example 1 of solid-state imaging device)

3. Second Embodiment (example 2 of solid-state imaging device)

4. Third Embodiment (example 3 of solid-state imaging device)

5. Fourth Embodiment (example 4 of solid-state imaging device)

6. Fifth Embodiment (example of electronic apparatus)

7. Use example of solid-state imaging device to which the present technology is applied

8. Application example to endoscopic surgical system

9. Application example to mobile body

### 1. Summary of the Present Technology

First, summary of the present technology will be described.

For a phase difference AF function and an HDR function, there is a pixel structure in which a single on-chip lens is manufactured in the same photodiode, and pixels are separated from each other by a dug oxide film or the like. However, in this pixel structure, light is condensed on an insulating film (SiO₂) in a center zone, and therefore there is a risk that light is scattered and color mixing increases. In addition, since a moth-eye structure is not formed, sensitivity is not amplified.

While achieving both a phase difference AF function and an HDR function, the present technology can prevent color mixing by absorbing and/or reflecting light that causes color mixing near a portion between a plurality of photoelectric converters (photodiodes) (a central separation zone of a pixel, the central separation zone being a light condensing portion of an on-chip lens) using a light absorbing member and/or a light reflecting member. Moreover, the present technology can increase sensitivity by combining a moth-eye structure to increase scattering of light and extend an optical path length. The present technology can increase sensitivity on a long wavelength side such as near-infrared light in addition to visible light.

Hereinafter, embodiments according to the present technology will be described in detail.

### 2. First Embodiment (Example 1 of Solid-State Imaging Device)

A solid-state imaging device according to a first embodiment (example 1 of solid-state imaging device) of the present technology is a solid-state imaging device including a plurality of pixels arranged therein, in which in each of the pixels, one on-chip lens that condenses incident light and at least one photoelectric converter formed in a semiconductor substrate are provided in order from a light incident side, at least one pixel among the plurality of pixels includes the one on-chip lens and the plurality of photoelectric converters, and between the plurality of photoelectric converters, a light absorbing member that absorbs at least a part of light condensed by the one on-chip lens is provided. In the solid-state imaging device according to the first embodiment (example 1 of solid-state imaging device) of the present technology, a trench may be formed between the plurality of photoelectric converters, a light absorbing member may be provided in at least a part of the trench, the light absorbing member and an insulating film may be provided in at least a part of the trench in order from a light incident side, and moreover, the light absorbing member may be provided above the trench on the light incident side.

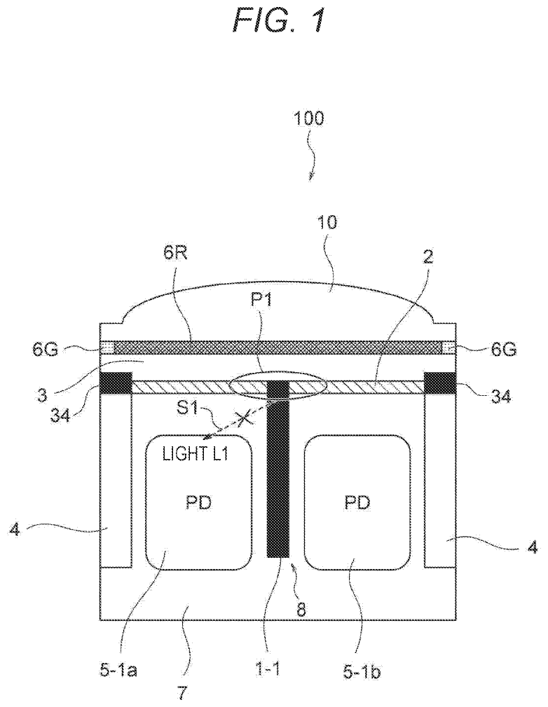

The solid-state imaging device according to the first embodiment of the present technology will be described with reference to FIGS. 1 to 3 and FIGS. 5 to 7. FIGS. 1 to 3 and FIGS. 5 to 7 are diagrams illustrating configuration examples of the solid-state imaging device according to the first embodiment of the present technology.

First, description will be made with reference to FIG. 1. FIG. 1 is a diagram illustrating a cross-sectional configuration example for one pixel of a solid-state imaging device 100 according to the first embodiment of the present technology.

The solid-state imaging device 100 (for one pixel) includes, in order from a light incident side, an on-chip lens 10 that condenses incident light, a color filter 6R (the color filter is a red (R) color filter in FIG. 1, but is not limited to the red (R) color filter), an insulating film 3 (for example, a silicon oxide (SiO₂) film), and two photoelectric converters 5-1a and 5-1b (photodiodes (PD)) formed in a semiconductor substrate 7. A light absorbing member 1-1 that absorbs at least a part of light condensed by the on-chip lens 10 (light condensed on spot P1) is provided between the photodiode 5-1a and the photodiode 5-1b. As illustrated in FIG. 1, light L1 (color mixing component) condensed on spot P1 is absorbed by the light absorbing member 1-1, and light L1 does not reach the photodiode 5-1a and is not scattered as indicated by an arrow (x mark) S1. As a result, color mixing can be prevented.

A portion (trench structure) 8 dug into a light receiving surface (upper side in FIG. 1) of the semiconductor substrate 7 is filled with the light absorbing member 1-1. The light absorbing member 1-1 contains tungsten (W).

In the trench structure 8, a photoresist is applied to an upper surface of the semiconductor substrate 7 on a light receiving surface side (back surface side, upper side in FIG. 1), and photoresist is patterned by a lithography technique such that a dug portion corresponding to the trench structure 8 is opened.

Then, an anisotropic dry etching process is performed on the semiconductor substrate 7 on the basis of the patterned photoresist to form the trench structure 8. Thereafter, the photoresist is removed. Therefore, the trench structure 8 is formed.

The trench structure 8 that needs to be dug to a deep position of the semiconductor substrate 7 is formed by the anisotropic etching process. Therefore, the trench structure 8 can have a non-tapered dug shape. Note that the trench structure 8 is not limited to a non-tapered dug shape as long as the trench structure 8 is filled with the light absorbing member 1-1, and may have a tapered shape or a reverse tapered shape.

Next, the light absorbing member 1-1 (tungsten (W) in FIG. 1) is formed by a film forming method with high embeddability such as a CVD method. Therefore, the inside of the dug trench structure 8 is filled with the light absorbing member 1-1 (tungsten (W) in FIG. 1). Then, a light shielding film 34 is formed on an insulating film 4 having a trench structure by a lithography technique in a region between pixels, and then the insulating film 3, the color filter 6R (and 6G), and the on-chip lens 10 are formed in this order.

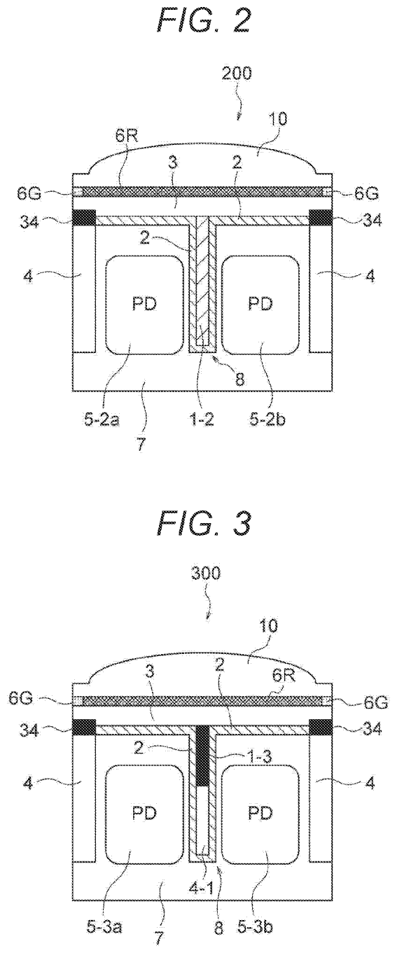

Next, description will be made with reference to FIG. 2. FIG. 2 is a diagram illustrating a cross-sectional configuration example for one pixel of a solid-state imaging device 200 according to the first embodiment of the present technology.

The solid-state imaging device 200 (for one pixel) includes, in order from a light incident side, an on-chip lens 10 that condenses incident light, a color filter 6R (the color filter is a red (R) color filter in FIG. 2, but is not limited to the red (R) color filter), an insulating film 3 (for example, a silicon oxide (SiO₂) film), and two photoelectric converters 5-2a and 5-2b (photodiodes (PD)) formed in a semiconductor substrate 7. A light absorbing member 1-2 that absorbs at least a part of light condensed by the on-chip lens 10 is provided between the photodiode 5-2a and the photodiode 5-2b.

A portion (trench structure) 8 dug into a light receiving surface (upper side in FIG. 2) of the semiconductor substrate 7 is filled with the light absorbing member 1-2 via a metal oxide film 2. The light absorbing member 1-2 contains, for example, at least one selected from the group consisting of aluminum (Al), copper (Cu), and a carbon-based material. The metal oxide film 2 functions as, for example, a pinning film, and may be formed using a high dielectric substance having a negative fixed charge such that a positive charge (hole) accumulation region is formed at an interface with the semiconductor substrate 7 to suppress generation of a dark current. By forming the metal oxide film 2 (pinning film) so as to have a negative fixed charge, an electric field is applied to the interface with the semiconductor substrate 7 by the negative fixed charge, and therefore a positive charge accumulation region is formed. The metal oxide film 2 (pinning film) is formed using, for example, hafnium oxide (HfO₂). Furthermore, the metal oxide film 2 (pinning film) may be formed using, for example, zirconium dioxide (ZrO₂) or tantalum oxide (Ta₂O₅). In addition, the metal oxide film 2 (pinning film) may have a configuration of a single-layer film including a single layer or a configuration of a laminated film including a plurality of layers.

In the trench structure 8, a photoresist is applied to an upper surface of the semiconductor substrate 7 on a light receiving surface side (back surface side, upper side in FIG. 2), and photoresist is patterned by a lithography technique such that a dug portion corresponding to the trench structure 8 is opened.

Then, an anisotropic dry etching process is performed on the semiconductor substrate 7 on the basis of the patterned photoresist to form the trench structure 8. Thereafter, the photoresist is removed. Therefore, the trench structure 8 is formed.

The trench structure 8 that needs to be dug to a deep position of the semiconductor substrate 7 is formed by the anisotropic etching process. Therefore, the trench structure 8 can have a non-tapered dug shape. Note that the trench structure 8 is not limited to a non-tapered dug shape as long as the trench structure 8 is filled with the light absorbing member 1-2, and may have a tapered shape or a reverse tapered shape.

Next, the metal oxide film 2 is formed by, for example, a chemical vapor deposition (CVD) method on an entire front surface (back surface) of the semiconductor substrate 7 in which the trench structure 8 is formed.

Then, the light absorbing member 1-2 (in FIG. 2, for example, at least one selected from the group consisting of aluminum (Al), copper (Cu), and a carbon-based material) is formed on an upper surface of the metal oxide film 2 by a film forming method with high embeddability such as a CVD method. Therefore, the inside of the dug trench structure 8 is filled with the light absorbing member 1-2 (in FIG. 2, for example, at least one selected from the group consisting of aluminum (Al), copper (Cu), and a carbon-based material) via the metal oxide film 2. Then, a light shielding film 34 is formed by a lithography technique in a region between pixels, and then the insulating film 3, the color filter 6R (and 6G), and the on-chip lens 10 are formed in this order.

Next, description will be made with reference to FIG. 3. FIG. 3 is a diagram illustrating a cross-sectional configuration example for one pixel of a solid-state imaging device 300 according to the first embodiment of the present technology.

The solid-state imaging device 300 (for one pixel) includes, in order from a light incident side, an on-chip lens 10 that condenses incident light, a color filter 6R (the color filter is a red (R) color filter in FIG. 3, but is not limited to the red (R) color filter), an insulating film 3 (for example, a silicon oxide (SiO₂) film), and two photoelectric converters 5-3a and 5-3b (photodiodes (PD)) formed in the semiconductor substrate 7. A light absorbing member 1-3 that absorbs at least a part of light condensed by the on-chip lens 10 is provided between the photodiode 5-3a and the photodiode 5-3b.

A portion (trench structure) 8 dug into a light receiving surface (upper side in FIG. 3) of the semiconductor substrate 7 is filled with the light absorbing member 1-3 via a metal oxide film 2 on an insulating film 4-1 (for example, a silicon oxide (SiO₂) film). That is, the trench structure 8 is filled with the light absorbing member 1-3 and the insulating film 4-1 in order from a light incident side (from an upper side to a lower side in FIG. 3). The filling amount of the light absorbing member 1-3 and the insulating film 4-1 can be changed depending on the wavelength of light. For example, in a case where short-wavelength light (B light) is absorbed, a light condensing point is shallow, and therefore the filling amount of the light absorbing member 1-3 can be reduced to shorten the length (vertical direction in FIG. 3) of the light absorbing member 1-3. In a case where long-wavelength light (R light) is absorbed, a light condensing point is deep, and therefore the filling amount of the light absorbing member 1-3 can be increased to lengthen the length (vertical direction in FIG. 3) of the light absorbing member 1-3. In FIG. 3, the light absorbing member 1-3 contains tungsten (W), but may contain, for example, at least one selected from the group consisting of aluminum (Al), copper (Cu), and a carbon-based material.

In the trench structure 8, a photoresist is applied to an upper surface of the semiconductor substrate 7 on a light receiving surface side (back surface side, upper side in FIG. 3), and photoresist is patterned by a lithography technique such that a dug portion corresponding to the trench structure 8 is opened.

Then, an anisotropic dry etching process is performed on the semiconductor substrate 7 on the basis of the patterned photoresist to form the trench structure 8. Thereafter, the photoresist is removed. Therefore, the trench structure 8 is formed.

The trench structure 8 that needs to be dug to a deep position of the semiconductor substrate 7 is formed by the anisotropic etching process. Therefore, the trench structure 8 can have a non-tapered dug shape. Note that the trench structure 8 is not limited to a non-tapered dug shape as long as the trench structure 8 is filled with the light absorbing member 1-3, and may have a tapered shape or a reverse tapered shape.

Next, the metal oxide film 2 is formed by, for example, a chemical vapor deposition (CVD) method on an entire front surface (back surface) of the semiconductor substrate 7 in which the trench structure 8 is formed.

Then, first, the insulating film 4-1 is formed on an upper surface of the metal oxide film 2 by a film forming method with high embeddability, for example, such as a CVD method, and the light absorbing member 1-3 (in FIG. 3, tungsten (W)) is formed by a film forming method with high embeddability such as a CVD method. Therefore, the inside of the dug trench structure 8 is filled with the light absorbing member 1-3 (in FIG. 3, tungsten (W)) via the metal oxide film 2 in order from a light incident side. Then, a light shielding film 34 is formed by a lithography technique in a region between pixels, and then the insulating film 3, the color filter 6R (and 6G), and the on-chip lens 10 are formed in this order.

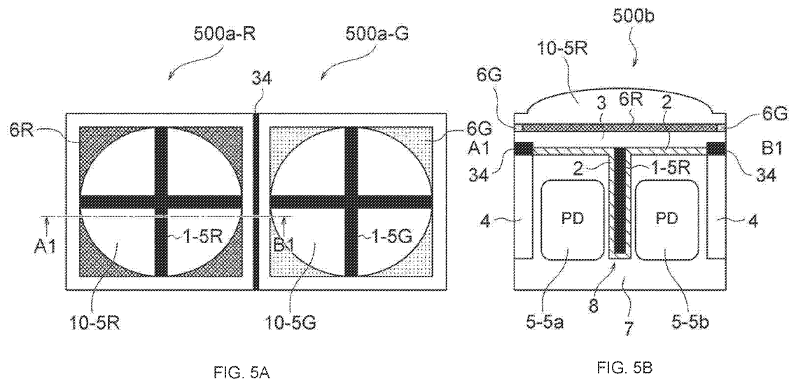

Next, description will be made with reference to FIG. 5. FIG. 5(a) is a plan layout diagram for two pixels of a solid-state imaging device 500 (500a-R and 500a-G) according to the first embodiment of the present technology as viewed from a light incident side. More specifically, the solid-state imaging device 500 (500a-R) is a plan layout diagram for one pixel in which a red (R) color filter is formed, and the solid-state imaging device 500 (500a-G) is a plan layout diagram for one pixel in which a green (G) color filter is formed. FIG. 5(b) is a diagram illustrating a cross-sectional configuration example for one pixel of the solid-state imaging device 500 (500b) according to the first embodiment of the present technology cut along A1-B1 illustrated in FIG. 5(a).

As illustrated in FIG. 5(b), the solid-state imaging device 500 (500b) (for one pixel) includes, in order from a light incident side, an on-chip lens 10-5R that condenses incident light, a color filter 6R (the color filter is a red (R) color filter in FIG. 5(b), but is not limited to the red (R) color filter), an insulating film 3, and two photoelectric converters 5-5a and 5-5b (photodiodes (PD)) formed in a semiconductor substrate 7. A light absorbing member 1-5R that absorbs at least a part of light condensed by the on-chip lens 10-5R is provided between the photodiode 5-5a and the photodiode 5-5b.

A portion (trench structure) 8 dug into a light receiving surface (upper side in FIG. 5(b)) of the semiconductor substrate 7 is filled with the light absorbing member 1-5R via a metal oxide film 2 In FIG. 5(b), the light absorbing member 1-5R contains tungsten (W), but may contain, for example, at least one selected from the group consisting of aluminum (Al), copper (Cu), and a carbon-based material.

In the trench structure 8, a photoresist is applied to an upper surface of the semiconductor substrate 7 on a light receiving surface side (back surface side, upper side in FIG. 5(b)), and photoresist is patterned by a lithography technique such that a dug portion corresponding to the trench structure 8 is opened.

Then, an anisotropic dry etching process is performed on the semiconductor substrate 7 on the basis of the patterned photoresist to form the trench structure 8. Thereafter, the photoresist is removed. Therefore, the trench structure 8 is formed.

The trench structure 8 that needs to be dug to a deep position of the semiconductor substrate 7 is formed by the anisotropic etching process. Therefore, the trench structure 8 can have a non-tapered dug shape. Note that the trench structure 8 is not limited to a non-tapered dug shape as long as the trench structure 8 is filled with the light absorbing member 1-5R, and may have a tapered shape or a reverse tapered shape.

Next, the metal oxide film 2 is formed by, for example, a chemical vapor deposition (CVD) method on an entire front surface (back surface) of the semiconductor substrate 7 in which the trench structure 8 is formed.

Then, the light absorbing member 1-5R (in FIG. 5, tungsten (W)) is formed on an upper surface of the metal oxide film 2 by a film forming method with high embeddability such as a CVD method. Therefore, the inside of the dug trench structure 8 is filled with the light absorbing member 1-5R (in FIG. 5, tungsten (W)) via the metal oxide film 2. Then, a light shielding film 34 is formed by a lithography technique in a region between pixels, and then the insulating film 3, the color filter 6R (and 6G), and the on-chip lens 10 are formed in this order.

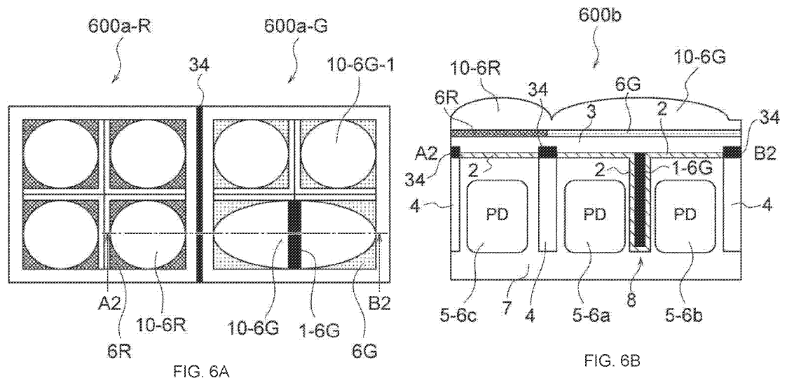

Description will be made with reference to FIG. 6. FIG. 6(a) is a plan layout diagram for seven pixels of a solid-state imaging device 600 (600a-R and 600a-G) according to the first embodiment of the present technology as viewed from a light incident side. More specifically, the solid-state imaging device 600 (600a-R) is a plan layout diagram for four pixels in which a red (R) color filter is formed, and the solid-state imaging device 600 (600a-G) is a plan layout diagram for three pixels in which a green (G) color filter is formed. FIG. 6(b) is a diagram illustrating a cross-sectional configuration example for two pixels of the solid-state imaging device 600 (600b) according to the first embodiment of the present technology cut along A2-B2 illustrated in FIG. 6(a).

As illustrated in FIG. 6(b), the right pixel in FIG. 6(b) of the solid-state imaging device 600 (600b) (for two pixels) includes, in order from a light incident side, an on-chip lens 10-6G that condenses incident light, a green (G) color filter 6G, an insulating film 3 (for example, a silicon oxide (SiO₂) film), and two photoelectric converters 5-6a and 5-6b (photodiodes (PD)) formed in a semiconductor substrate 7. A light absorbing member 1-6G that absorbs at least a part of light condensed by the on-chip lens 10-6G is provided between the photodiode 5-6a and the photodiode 5-6b. The left pixel in FIG. 6(b) of the solid-state imaging device 600 (600b) (for two pixels) includes, in order from a light incident side, an on-chip lens 10-6R that condenses incident light, a red (R) color filter 6R, the insulating film 3, and one photoelectric converter 5-6c (photodiode (PD)) formed in the semiconductor substrate 7. A trench structure is formed between the photodiode 5-6a and the photodiode 5-6c (between two pixels), and an insulating film 4 (for example, a silicon oxide (SiO₂) film) filled inside the trench structure is formed. By the way, the right pixel in FIG. 6(b) of the solid-state imaging device 600 (600b) (for two pixels) may be a phase difference detection pixel (image plane phase difference pixel) that generates a pixel signal used for phase difference signal calculation for controlling an image plane phase difference AF that is one AF function system, and the left pixel in FIG. 6(b) of the solid-state imaging device 600 (600b) (for two pixels) may be a normal pixel (imaging pixel) that generates a pixel signal of an image.

A portion (trench structure) 8 dug into a light receiving surface (upper side in FIG. 6(b)) of the semiconductor substrate 7 is filled with the light absorbing member 1-6G via a metal oxide film 2 In FIG. 6(b), the light absorbing member 1-6G contains tungsten (W), but may contain, for example, at least one selected from the group consisting of aluminum (Al), copper (Cu), and a carbon-based material. Since a method for manufacturing the light absorbing member 1-6G is similar to the method for manufacturing the light absorbing member 1-5R described above, description thereof is omitted here.

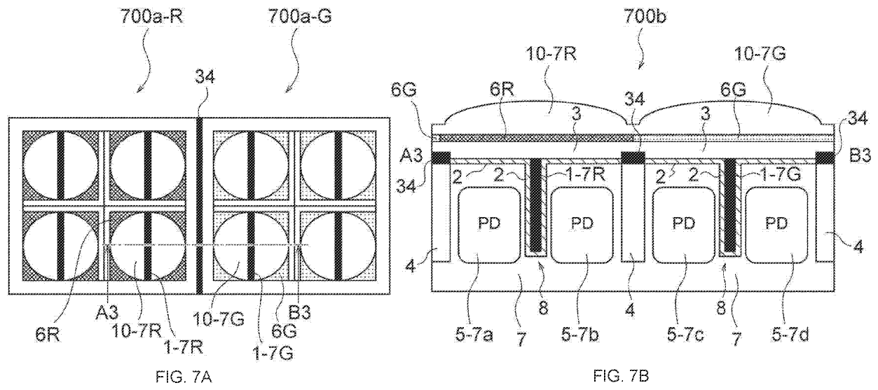

Description will be made with reference to FIG. 7. FIG. 7(a) is a plan layout diagram for eight pixels of a solid-state imaging device 700 (700a-R and 700a-G) according to the first embodiment of the present technology as viewed from a light incident side. More specifically, the solid-state imaging device 700 (700a-R) is a plan layout diagram for four pixels in which a red (R) color filter is formed, and the solid-state imaging device 700 (700a-G) is a plan layout diagram for four pixels in which a green (G) color filter is formed. FIG. 7(b) is a diagram illustrating a cross-sectional configuration example for two pixels of the solid-state imaging device 700 (700b) according to the first embodiment of the present technology cut along A3-B3 illustrated in FIG. 7(a).

As illustrated in FIG. 7(b), the right pixel in FIG. 7(b) of the solid-state imaging device 700 (700b) (for two pixels) includes, in order from a light incident side, an on-chip lens 10-7G that condenses incident light, a green (G) color filter 6G, an insulating film 3 (for example, a silicon oxide (SiO₂) film), and two photoelectric converters 5-7c and 5-7d (photodiodes (PD)) formed in a semiconductor substrate 7. A light absorbing member 1-7G that absorbs at least a part of light condensed by the on-chip lens 10-7G is provided between the photodiode 5-7c and the photodiode 5-7d. The left pixel in FIG. 7(b) of the solid-state imaging device 700 (700b) (for two pixels) includes, in order from a light incident side, an on-chip lens 10-7R that condenses incident light, a red (R) color filter 6R, the insulating film 3 (for example, a silicon oxide (SiO₂) film), and two photoelectric converters 5-7a and 5-7b (photodiodes (PD)) formed in the semiconductor substrate 7. A light absorbing member 1-7R that absorbs at least a part of light condensed by the on-chip lens 10-7R is provided between the photodiode 5-7a and the photodiode 5-7b. A trench structure is formed between the photodiode 5-7b and the photodiode 5-7c (between two pixels), and the insulating film 4 (for example, a silicon oxide (SiO₂) film) filled inside the trench structure is formed. By the way, the right and left pixels (pixels for two pixels) in FIG. 7(b) of the solid-state imaging device 700 (700b) (for two pixels) may be phase difference detection pixels (image plane phase difference pixels) that generate a pixel signal used for phase difference signal calculation for controlling an image plane phase difference AF that is one AF function system.

Portions (trench structures) 8 dug into a light receiving surface (upper side in FIG. 6(b)) of the semiconductor substrate 7 are filled with the light absorbing members 1-7G and 1-7R via a metal oxide film 2, respectively. In FIG. 7(b), the light absorbing members 1-7G and 1-7R each contain tungsten (W), but may each contain, for example, at least one selected from the group consisting of aluminum (Al), copper (Cu), and a carbon-based material. Since a method for manufacturing the light absorbing members 1-7G and 1-7R is similar to the method for manufacturing the light absorbing member 1-5R described above, description thereof is omitted here.

As described above, the contents described for the solid-state imaging device according to the first embodiment (example 1 of solid-state imaging device) of the present technology can be applied to solid-state imaging devices according to second to fourth embodiments of the present technology described later unless there is a particular technical contradiction.

### 3. Second Embodiment (Example 2 of Solid-State Imaging Device)

A solid-state imaging device according to a second embodiment (example 2 of solid-state imaging device) of the present technology is a solid-state imaging device including a plurality of pixels arranged therein, in which in each of the pixels, one on-chip lens that condenses incident light and at least one photoelectric converter formed in a semiconductor substrate are provided in order from a light incident side, at least one pixel among the plurality of pixels includes the one on-chip lens and the plurality of photoelectric converters, and between the plurality of photoelectric converters, a light reflecting member that reflects at least a part of light condensed by the one on-chip lens is provided. In the solid-state imaging device according to the second embodiment (example 2 of solid-state imaging device) of the present technology, a trench may be formed between the plurality of photoelectric converters, a light reflecting member may be provided above the trench on a light incident side, the light reflecting member may be provided in at least a part of the trench, and moreover, the light reflecting member and an insulating film may be provided in at least a part of the trench in order from the light incident side.

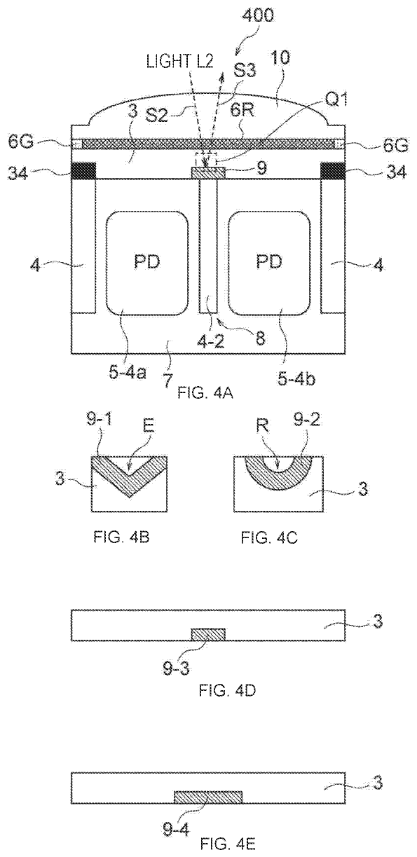

The solid-state imaging device according to the second embodiment of the present technology will be described with reference to FIG. 4. FIG. 4 is a diagram illustrating a configuration example of the solid-state imaging device according to the second embodiment of the present technology. More specifically, FIG. 4(a) is a diagram illustrating a cross-sectional configuration example for one pixel of a solid-state imaging device 400 according to the second embodiment of the present technology. FIG. 4(b) is a diagram illustrating a cross-sectional configuration example of a light reflecting member 9-1 having an edge structure E that can be provided in the solid-state imaging device 400 according to the second embodiment of the present technology. FIG. 4(c) is a diagram illustrating a cross-sectional configuration example of a light reflecting member 9-2 having a curved surface structure R that can be provided in the solid-state imaging device 400 according to the second embodiment of the present technology. FIG. 4(d) is a diagram illustrating a cross-sectional configuration example of a light reflecting member 9-3 having a flat structure that can be provided in the solid-state imaging device 400 according to the second embodiment of the present technology. FIG. 4(e) is a diagram illustrating a cross-sectional configuration example of a light reflecting member 9-4 having a flat structure that can be provided in the solid-state imaging device 400 according to the second embodiment of the present technology. Note that the width of the flat structure of the light reflecting member 9-4 (the length in a left-right direction in FIG. 4(e)) is larger than the width of the flat structure of the light reflecting member 9-3 (the length in a left-right direction in FIG. 4(d)).

As illustrated in FIG. 4, the solid-state imaging device 400 (for one pixel) includes, in order from a light incident side, an on-chip lens 10 that condenses incident light, a color filter 6R (the color filter is a red (R) color filter in FIG. 4, but is not limited to the red (R) color filter), an insulating film 3 (for example, a silicon oxide (SiO₂) film), and two photoelectric converters 5-4a and 5-4b (photodiodes (PD)) formed in a semiconductor substrate 7. An insulating film 4-2 with which the trench structure 8 is filled is provided between the photodiode 5-4a and the photodiode 5-4b. A light reflecting member 9 is formed above the trench structure 8 on a light incident side. The solid-state imaging device 400 can be manufactured by, for example, the method for manufacturing the solid-state imaging device 100 described above.

Since incident light L2 travels in a direction of arrow S2, light L2 is reflected by the light reflecting member 9 (part Q1 in FIG. 4), travels in a direction of arrow S3, and is emitted to the outside of the solid-state imaging device 400, the incident light near a portion (central separation zone of a pixel) between the photodiode 5-4a and the photodiode 5-4b is not absorbed by the photodiode 5-4a or the photodiode 5-4b, and color mixing can be prevented. The light reflecting member 9 is not limited as long as the light reflecting member 9 contains a material having a refractive index lower than the refractive index of the insulating film 3, but contains, for example, silver (Ag) or gold (Au).

As illustrated in FIG. 4(b), the light reflecting member may be a light reflecting member 9-1 having an edge structure E obtained by processing a surface of the light reflecting member, or as illustrated in FIG. 4(c), the light reflecting member may be a light reflecting member 9-2 having a curved surface structure R obtained by processing the surface of the light reflecting member. Light can be reflected by the light reflecting member 9-1 and the light reflecting member 9-2.

As illustrated in FIGS. 4(d) and 4(e), since the width of the flat structure of the light reflecting member 9-4 (the length in a left-right direction in FIG. 4(e)) is larger than the width of the flat structure of the light reflecting member 9-3 (the length in a left-right direction in FIG. 4(d)), light reflectivity can be enhanced and color mixing can be further prevented, but sensitivity may decrease in proportion to reflected light with enhanced reflectivity. Therefore, the width of the flat structure of the light reflecting member needs to be determined in consideration of a balance between color mixing prevention and sensitivity increase.

As described above, the contents described for the solid-state imaging device according to the second embodiment (example 2 of solid-state imaging device) of the present technology can be applied to the solid-state imaging device according to the first embodiment of the present technology described above and solid-state imaging devices according to third and fourth embodiments of the present technology described later unless there is a particular technical contradiction.

### 4. Third Embodiment (Example 3 of Solid-State Imaging Device)

A solid-state imaging device according to a third embodiment (example 3 of solid-state imaging device) of the present technology is a solid-state imaging device including a plurality of pixels arranged therein, in which in each of the pixels, one on-chip lens that condenses incident light and at least one photoelectric converter formed in a semiconductor substrate are provided in order from a light incident side, at least one pixel among the plurality of pixels includes the one on-chip lens and the plurality of photoelectric converters, between the plurality of photoelectric converters, a light absorbing member that absorbs at least a part of light condensed by the one on-chip lens is provided, and a moth-eye structure is formed on a light receiving surface side of the semiconductor substrate above the photoelectric converter. In the solid-state imaging device according to the third embodiment (example 3 of solid-state imaging device) of the present technology, a trench may be formed between the plurality of photoelectric converters, a light absorbing member may be provided in at least a part of the trench, the light absorbing member and an insulating film may be provided in at least a part of the trench in order from a light incident side, and moreover, the light absorbing member may be provided above the trench on the light incident side.

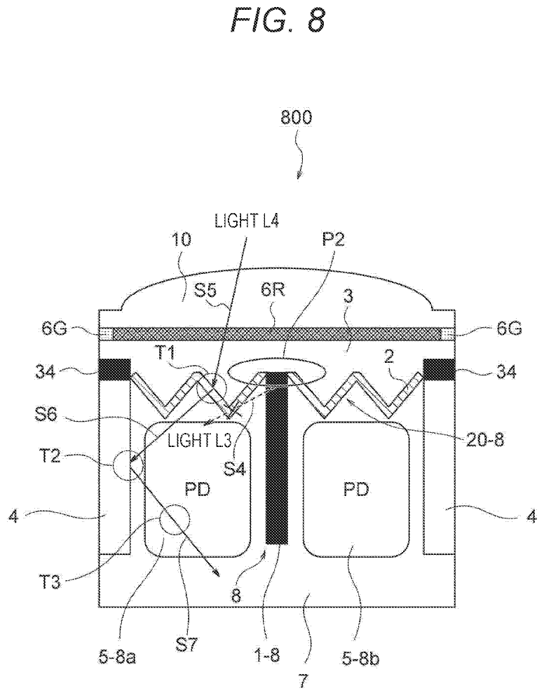

The solid-state imaging device according to the third embodiment of the present technology will be described with reference to FIGS. 8 to 10 and FIGS. 12 to 14. FIGS. 8 to 10 and FIGS. 12 to 14 are diagrams illustrating configuration examples of the solid-state imaging device according to the third embodiment of the present technology.

First, description will be made with reference to FIG. 8. FIG. 8 is a diagram illustrating a cross-sectional configuration example for one pixel of a solid-state imaging device 800 according to the third embodiment of the present technology.

The solid-state imaging device 800 (for one pixel) includes, in order from a light incident side, an on-chip lens 10 that condenses incident light, a color filter 6R (the color filter is a red (R) color filter in FIG. 1, but is not limited to the red (R) color filter), an insulating film 3 (for example, a silicon oxide (SiO₂) film), and two photoelectric converters 5-8a and 5-8b (photodiodes (PD)) formed in a semiconductor substrate 7. A light absorbing member 1-8 that absorbs at least a part of light condensed by the on-chip lens 10 (light condensed on spot P2) is provided between the photodiode 5-8a and the photodiode 5-8b. As illustrated in FIG. 8, light L3 (color mixing component) condensed on spot P2 is absorbed by the light absorbing member 1-8, and light L3 does not reach the photodiode 5-8a as indicated by arrow S4. As a result, color mixing can be prevented.

In the solid-state imaging device 800, an antireflector 20-8 having a moth-eye structure having a fine uneven structure is formed on a light receiving surface side of the semiconductor substrate 7 above the two photoelectric converters 5-8a and 5-8b (photodiodes (PD)). The antireflector 20-8 having a moth-eye structure can amplify sensitivity attenuated by prevention of color mixing by the light absorbing member 1-9.

As illustrated in FIG. 8, incident light L4 travels in order of arrow S5, arrow S6, and arrow S7, but light refraction is less likely to occur at point T1 of the antireflector 20-8 having a moth-eye structure, reflection of light is reduced, light travels in a direction of arrow S6, light is reflected by the insulating film 4 having a trench structure formed between pixels (point T2), light is absorbed by the photodiode 5-8c (point T3), and sensitivity is amplified.

A portion (trench structure) 8 dug into a light receiving surface (upper side in FIG. 8) of the semiconductor substrate 7 is filled with the light absorbing member 1-8. The light absorbing member 1-8 contains tungsten (W).

A photoresist is applied to an upper surface of the semiconductor substrate 7 on a back surface side, and the photoresist is patterned by a lithography technique such that a portion to be a recess of the moth-eye structure of the antireflector 20-8 is opened.

By performing dry etching processing on the semiconductor substrate 7 on the basis of the patterned photoresist, a recess of the moth-eye structure of the antireflector 20-8 is formed, and then the photoresist is removed. Note that the moth-eye structure of the antireflector 20-8 can be formed not by dry etching but also by wet etching.

In the trench structure 8, a photoresist is applied to an upper surface of the semiconductor substrate 7 on a light receiving surface side (back surface side, upper side in FIG. 8), and photoresist is patterned by a lithography technique such that a dug portion corresponding to the trench structure 8 is opened.

Then, an anisotropic dry etching process is performed on the semiconductor substrate 7 on the basis of the patterned photoresist to form the trench structure 8. Thereafter, the photoresist is removed. Therefore, the trench structure 8 is formed.

The trench structure 8 that needs to be dug to a deep position of the semiconductor substrate 7 is formed by the anisotropic etching process. Therefore, the trench structure 8 can have a non-tapered dug shape. Note that the trench structure 8 is not limited to a non-tapered dug shape as long as the trench structure 8 is filled with the light absorbing member 1-8, and may have a tapered shape or a reverse tapered shape.

A metal oxide film 2 is formed by, for example, a chemical vapor deposition (CVD) method on an entire front surface (back surface) of the semiconductor substrate 7 in which the antireflector 20-8 having a moth-eye structure is formed. Note that although not illustrated in FIG. 8, the metal oxide film 2 may be formed by, for example, a chemical vapor deposition (CVD) method on an entire front surface (back surface) of the semiconductor substrate 7 in which the trench structure 8 is formed.

As described above, the metal oxide film 2 functions as, for example, a pinning film, and may be formed using a high dielectric substance having a negative fixed charge such that a positive charge (hole) accumulation region is formed at an interface with the semiconductor substrate 7 to suppress generation of a dark current. By forming the metal oxide film 2 (pinning film) so as to have a negative fixed charge, an electric field is applied to the interface with the semiconductor substrate 7 by the negative fixed charge, and therefore a positive charge accumulation region is formed. The metal oxide film 2 (pinning film) is formed using, for example, hafnium oxide (HfO₂). Furthermore, the metal oxide film 2 (pinning film) may be formed using, for example, zirconium dioxide (ZrO₂) or tantalum oxide (Ta₂O₅). In addition, the metal oxide film 2 (pinning film) may have a configuration of a single-layer film including a single layer or a configuration of a laminated film including a plurality of layers.

Next, the light absorbing member 1-8 (tungsten (W) in FIG. 8) is formed by a film forming method with high embeddability such as a CVD method. Therefore, the inside of the dug trench structure 8 is filled with the light absorbing member 1-8 (tungsten (W) in FIG. 8).

Then, a light shielding film 34 is formed by a lithography technique in a region between pixels, and then the insulating film 3, the color filter 6R (and 6G), and the on-chip lens 10 are formed in this order.

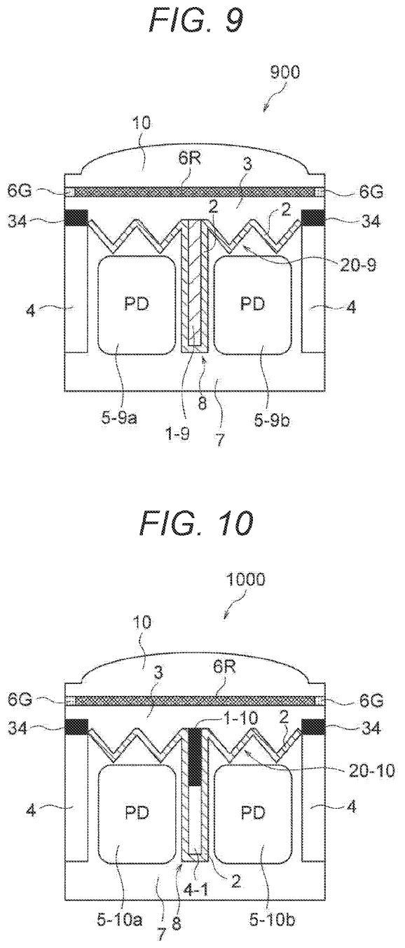

Description will be made with reference to FIG. 9. FIG. 9 is a diagram illustrating a cross-sectional configuration example for one pixel of a solid-state imaging device 900 according to the third embodiment of the present technology.

The solid-state imaging device 900 (for one pixel) includes, in order from a light incident side, an on-chip lens 10 that condenses incident light, a color filter 6R (the color filter is a red (R) color filter in FIG. 9, but is not limited to the red (R) color filter), an insulating film 3 (for example, a silicon oxide (SiO₂) film), and two photoelectric converters 5-9a and 5-9b (photodiodes (PD)) formed in a semiconductor substrate 7. A light absorbing member 1-9 that absorbs at least a part of light condensed by the on-chip lens 10 is provided between the photodiode 5-9a and the photodiode 5-9b.

In the solid-state imaging device 900, an antireflector 20-9 having a moth-eye structure having a fine uneven structure is formed on a light receiving surface side of the semiconductor substrate 7 above the two photoelectric converters 5-9a and 5-9b (photodiodes (PD)). The antireflector 20-9 having a moth-eye structure can amplify sensitivity attenuated by prevention of color mixing by the light absorbing member 1-9.

A portion (trench structure) 8 dug into a light receiving surface (upper side in FIG. 9) of the semiconductor substrate 7 is filled with the light absorbing member 1-9 via a metal oxide film 2 The light absorbing member 1-9 contains, for example, at least one selected from the group consisting of aluminum (Al), copper (Cu), and a carbon-based material.

In the trench structure 8, a photoresist is applied to an upper surface of a light receiving surface side (back surface side, upper side in FIG. 9) of the semiconductor substrate 7, and photoresist is patterned by a lithography technique such that a dug portion corresponding to the trench structure 8 is opened.

Then, an anisotropic dry etching process is performed on the semiconductor substrate 7 on the basis of the patterned photoresist to form the trench structure 8. Thereafter, the photoresist is removed. Therefore, the trench structure 8 is formed.

The trench structure 8 that needs to be dug to a deep position of the semiconductor substrate 7 is formed by the anisotropic etching process. Therefore, the trench structure 8 can have a non-tapered dug shape. Note that the trench structure 8 is not limited to a non-tapered dug shape as long as the trench structure 8 is filled with the light absorbing member 1-9, and may have a tapered shape or a reverse tapered shape.

Next, the metal oxide film 2 is formed by, for example, a chemical vapor deposition (CVD) method on an entire front surface (back surface) of the semiconductor substrate 7 in which the antireflector 20-9 having a moth-eye structure and the trench structure 8 are formed.

Then, the light absorbing member 1-9 (in FIG. 9, for example, at least one selected from the group consisting of aluminum (Al), copper (Cu), and a carbon-based material) is formed on an upper surface of the metal oxide film 2 by a film forming method with high embeddability such as a CVD method. Therefore, the inside of the dug trench structure 8 is filled with the light absorbing member 1-9 (in FIG. 9, for example, at least one selected from the group consisting of aluminum (Al), copper (Cu), and a carbon-based material) via the metal oxide film 2. Then, a light shielding film 34 is formed by a lithography technique in a region between pixels, and then the insulating film 3, the color filter 6R (and 6G), and the on-chip lens 10 are formed in this order.

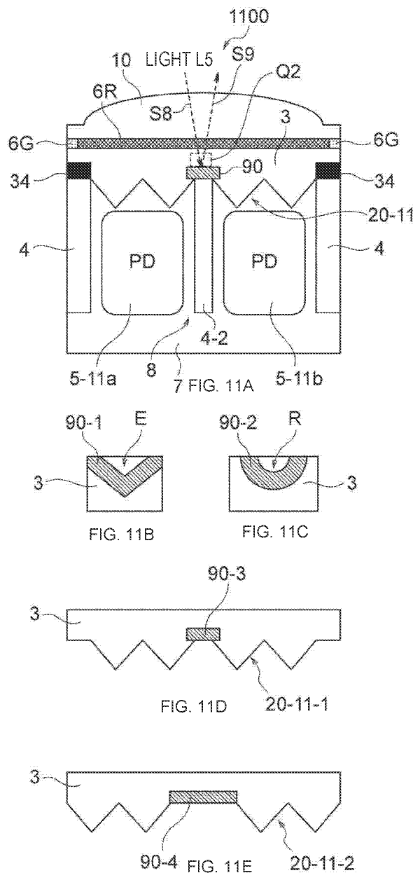

Description will be made with reference to FIG. 10. FIG. 10 is a diagram illustrating a cross-sectional configuration example for one pixel of a solid-state imaging device 1000 according to the third embodiment of the present technology.

The solid-state imaging device 1000 (for one pixel) includes, in order from a light incident side, an on-chip lens 10 that condenses incident light, a color filter 6R (the color filter is a red (R) color filter in FIG. 3, but is not limited to the red (R) color filter), an insulating film 3 (for example, a silicon oxide (SiO₂) film), and two photoelectric converters 5-10a and 5-10b (photodiodes (PD)) formed in a semiconductor substrate 7. A light absorbing member 1-10 that absorbs at least a part of light condensed by the on-chip lens 10 is provided between the photodiode 5-10a and the photodiode 5-10b.

In the solid-state imaging device 1000, an antireflector 20-10 having a moth-eye structure having a fine uneven structure is formed on a light receiving surface side of the semiconductor substrate 7 above the two photoelectric converters 5-10a and 5-10b (photodiodes (PD)). The antireflector 20-10 having a moth-eye structure can amplify sensitivity attenuated by prevention of color mixing by the light absorbing member 1-10.

A portion (trench structure) 8 dug into a light receiving surface (upper side in FIG. 10) of the semiconductor substrate 7 is filled with the light absorbing member 1-10 via the metal oxide film 2 on the insulating film 4-1 (for example, a silicon oxide (SiO₂) film). That is, the trench structure 8 is filled with the light absorbing member 1-10 and the insulating film 4-1 in order from a light incident side (from an upper side to a lower side in FIG. 10). In FIG. 10, the light absorbing member 1-10 contains tungsten (W), but may contain, for example, at least one selected from the group consisting of aluminum (Al), copper (Cu), and a carbon-based material.

In the trench structure 8, a photoresist is applied to an upper surface of the semiconductor substrate 7 on a light receiving surface side (back surface side, upper side in FIG. 10), and photoresist is patterned by a lithography technique such that a dug portion corresponding to the trench structure 8 is opened.

Then, an anisotropic dry etching process is performed on the semiconductor substrate 7 on the basis of the patterned photoresist to form the trench structure 8. Thereafter, the photoresist is removed. Therefore, the trench structure 8 is formed.

The trench structure 8 that needs to be dug to a deep position of the semiconductor substrate 7 is formed by the anisotropic etching process. Therefore, the trench structure 8 can have a non-tapered dug shape. Note that the trench structure 8 is not limited to a non-tapered dug shape as long as the trench structure 8 is filled with the light absorbing member 1-10, and may have a tapered shape or a reverse tapered shape.

Next, the metal oxide film 2 is formed by, for example, a chemical vapor deposition (CVD) method on an entire front surface (back surface) of the semiconductor substrate 7 in which the antireflector 20-10 having a moth-eye structure and the trench structure 8 are formed.

Then, first, the insulating film 4-1 is formed on an upper surface of the metal oxide film 2 by a film forming method with high embeddability, for example, such as a CVD method, and the light absorbing member 1-10 (in FIG. 10, tungsten (W)) is formed by a film forming method with high embeddability such as a CVD method. Therefore, the inside of the dug trench structure 8 is filled with the light absorbing member 1-10 (in FIG. 10, tungsten (W)) via the metal oxide film 2 in order from a light incident side. Then, a light shielding film 34 is formed by a lithography technique in a region between pixels, and then the insulating film 3, the color filter 6R (and 6G), and the on-chip lens 10 are formed in this order.

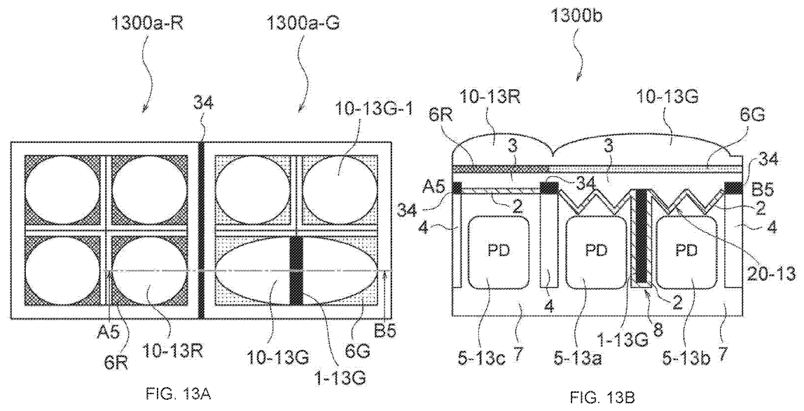

Description will be made with reference to FIG. 12. FIG. 12(a) is a plan layout diagram for two pixels of a solid-state imaging device 1200 (1200a-R and 1200a-G) according to the third embodiment of the present technology as viewed from a light incident side. More specifically, the solid-state imaging device 1200 (1200a-R) is a plan layout diagram for one pixel in which a red (R) color filter is formed, and the solid-state imaging device 1200 (1200a-G) is a plan layout diagram for one pixel in which a green (G) color filter is formed. FIG. 12(b) is a diagram illustrating a cross-sectional configuration example for one pixel of the solid-state imaging device 1200 (1200b) according to the third embodiment of the present technology cut along A4-B4 illustrated in FIG. 12(a).

As illustrated in FIG. 12(b), the solid-state imaging device 1200 (1200b) (for one pixel) includes, in order from a light incident side, an on-chip lens 10-12R that condenses incident light, the color filter 6R (the color filter is a red (R) color filter in FIG. 12(b), but is not limited to the red (R) color filter), the insulating film 3, and two photoelectric converters 5-12a and 5-12b (photodiodes (PD)) formed in the semiconductor substrate 7. A light absorbing member 1-12R that absorbs at least a part of light condensed by the on-chip lens 10-12R is provided between the photodiode 5-12a and the photodiode 5-12b.

In the solid-state imaging device 1200 (1200b), an antireflector 20-12 having a moth-eye structure having a fine uneven structure is formed on a light receiving surface side of the semiconductor substrate 7 above the two photoelectric converters 5-12a and 5-12b (photodiodes (PD)). The antireflector 20-12 having a moth-eye structure can amplify sensitivity attenuated by prevention of color mixing by the light absorbing member 1-12R.

A portion (trench structure) 8 dug into a light receiving surface (upper side in FIG. 12(b)) of the semiconductor substrate 7 is filled with the light absorbing member 1-12R via the metal oxide film 2 In FIG. 12(b), the light absorbing member 1-12R contains tungsten (W), but may contain, for example, at least one selected from the group consisting of aluminum (Al), copper (Cu), and a carbon-based material.

In the trench structure 8, a photoresist is applied to an upper surface of the semiconductor substrate 7 on a light receiving surface side (back surface side, upper side in FIG. 12(b)), and photoresist is patterned by a lithography technique such that a dug portion corresponding to the trench structure 8 is opened.

Then, an anisotropic dry etching process is performed on the semiconductor substrate 7 on the basis of the patterned photoresist to form the trench structure 8. Thereafter, the photoresist is removed. Therefore, the trench structure 8 is formed.

The trench structure 8 that needs to be dug to a deep position of the semiconductor substrate 7 is formed by the anisotropic etching process. Therefore, the trench structure 8 can have a non-tapered dug shape. Note that the trench structure 8 is not limited to a non-tapered dug shape as long as the trench structure 8 is filled with the light absorbing member 1-12R, and may have a tapered shape or a reverse tapered shape.

Next, the metal oxide film 2 is formed by, for example, a chemical vapor deposition (CVD) method on an entire front surface (back surface) of the semiconductor substrate 7 in which the antireflector 20-12 having a moth-eye structure and the trench structure 8 are formed.

Then, the light absorbing member 1-12R (in FIG. 12(b), tungsten (W)) is formed on an upper surface of the metal oxide film 2 by a film forming method with high embeddability such as a CVD method. Therefore, the inside of the dug trench structure 8 is filled with the light absorbing member 1-12R (in FIG. 5, tungsten (W)) via the metal oxide film 2. Then, a light shielding film 34 is formed by a lithography technique in a region between pixels, and then the insulating film 3, the color filter 6R (and 6G), and the on-chip lens 10 are formed in this order.

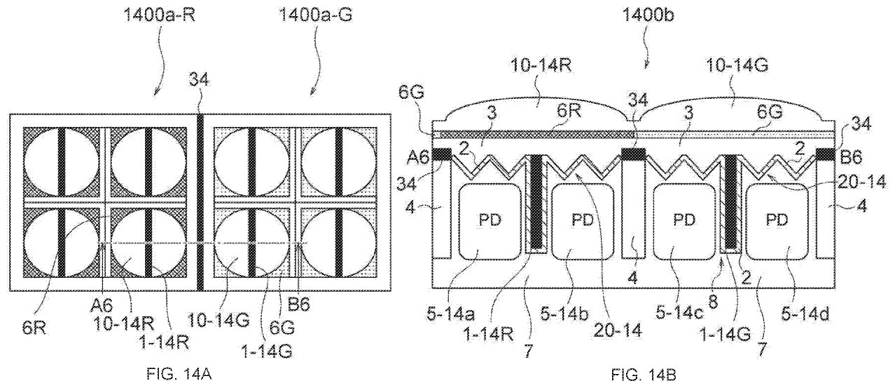

Description will be made with reference to FIG. 13. FIG. 13(a) is a plan layout diagram for seven pixels of a solid-state imaging device 1300 (1300a-R and 1300a-G) according to the third embodiment of the present technology as viewed from a light incident side. More specifically, the solid-state imaging device 1300 (1300a-R) is a plan layout diagram for four pixels in which a red (R) color filter is formed, and the solid-state imaging device 1300 (1300a-G) is a plan layout diagram for three pixels in which a green (G) color filter is formed. FIG. 13(b) is a diagram illustrating a cross-sectional configuration example for two pixels of the solid-state imaging device 1300 (1300b) according to the third embodiment of the present technology cut along A5-B5 illustrated in FIG. 13(a).

As illustrated in FIG. 13(b), the right pixel in FIG. 13(b) of the solid-state imaging device 1300 (1300b) (for two pixels) includes, in order from a light incident side, an on-chip lens 10-13G that condenses incident light, a green (G) color filter 6G, the insulating film 3 (for example, a silicon oxide (SiO₂) film), and two photoelectric converters 5-13a and 5-13b (photodiodes (PD)) formed in the semiconductor substrate 7. A light absorbing member 1-13G that absorbs at least a part of light condensed by the on-chip lens 10-13G is provided between the photodiode 5-13a and the photodiode 5-13b. The left pixel in FIG. 13(b) of the solid-state imaging device 1300 (1300b) (for two pixels) includes, in order from a light incident side, an on-chip lens 10-13R that condenses incident light, a red (R) color filter 6R, the insulating film 3, and one photoelectric converter 5-13c (photodiode (PD)) formed in the semiconductor substrate 7. A trench structure is formed between the photodiode 5-13a and the photodiode 5-13c (between two pixels), and the insulating film 4 (for example, a silicon oxide (SiO₂) film) filled inside the trench structure is formed. By the way, the right pixel in FIG. 13(b) of the solid-state imaging device 1300 (1300b) (for two pixels) may be a phase difference detection pixel (image plane phase difference pixel) that generates a pixel signal used for phase difference signal calculation for controlling an image plane phase difference AF that is one AF function system, and the left pixel in FIG. 13(b) of the solid-state imaging device 1300 (1300b) (for two pixels) may be a normal pixel (imaging pixel) that generates a pixel signal of an image.

In the solid-state imaging device 1300 (1300b), an antireflector 20-13 having a moth-eye structure having a fine uneven structure is formed on a light receiving surface side of the semiconductor substrate 7 above the two photoelectric converters 5-13a and 5-13b (photodiodes (PD)). The antireflector 20-13 having a moth-eye structure can amplify sensitivity attenuated by prevention of color mixing by the light absorbing member 1-13G.

A portion (trench structure) 8 dug into a light receiving surface (upper side in FIG. 13(b)) of the semiconductor substrate 7 is filled with the light absorbing member 1-13G via the metal oxide film 2 In FIG. 13(b), the light absorbing member 1-13G contains tungsten (W), but may contain, for example, at least one selected from the group consisting of aluminum (Al), copper (Cu), and a carbon-based material. Since a method for manufacturing the light absorbing member 1-13G is similar to the method for manufacturing the light absorbing member 1-12R described above, description thereof is omitted here.

Description will be made with reference to FIG. 14. FIG. 14(a) is a plan layout diagram for eight pixels of a solid-state imaging device 1400 (1400a-R and 1400a-G) according to the third embodiment of the present technology as viewed from a light incident side. More specifically, the solid-state imaging device 1400 (1400a-R) is a plan layout diagram for four pixels in which a red (R) color filter is formed, and the solid-state imaging device 1400 (1400a-G) is a plan layout diagram for four pixels in which a green (G) color filter is formed. FIG. 14(b) is a diagram illustrating a cross-sectional configuration example for two pixels of the solid-state imaging device 1400 (1400b) according to the third embodiment of the present technology cut along A6-B6 illustrated in FIG. 14(a).

As illustrated in FIG. 14(b), the right pixel in FIG. 14(b) of the solid-state imaging device 1400 (1400b) (for two pixels) includes, in order from a light incident side, an on-chip lens 10-14G that condenses incident light, a green (G) color filter 6G, the insulating film 3 (for example, a silicon oxide (SiO₂) film), and two photoelectric converters 5-14c and 5-14d (photodiodes (PD)) formed in the semiconductor substrate 7. A light absorbing member 1-14G that absorbs at least a part of light condensed by the on-chip lens 10-14G is provided between the photodiode 5-14c and the photodiode 5-14d. In the left pixel in FIG. 14(b) of the solid-state imaging device 1400 (700b) (for two pixels), in order from a light incident side, an on-chip lens 10-14R that condenses incident light, a red (R) color filter 6R, the insulating film 3 (for example, a silicon oxide (SiO₂) film), and two photoelectric converters 5-14a and 5-14b (photodiodes (PD)) formed in the semiconductor substrate 7. A light absorbing member 1-14R that absorbs at least a part of light condensed by the on-chip lens 10-14R is provided between the photodiode 5-14a and the photodiode 5-14b. A trench structure is formed between the photodiode 5-14b and the photodiode 5-14c (between two pixels), and the insulating film 4 (for example, a silicon oxide (SiO₂) film) filled inside the trench structure is formed. By the way, the right and left pixels (pixels for two pixels) in FIG. 14(b) of the solid-state imaging device 1400 (1400b) (for two pixels) may be phase difference detection pixels (image plane phase difference pixels) that generate a pixel signal used for phase difference signal calculation for controlling an image plane phase difference AF that is one AF function system.

In the solid-state imaging device 1400 (1400b), an antireflector 20-14 having a moth-eye structure having a fine uneven structure is formed on a light receiving surface side of the semiconductor substrate 7 above the two photoelectric converters 5-14a and 5-14b (photodiodes (PD)) and the two photoelectric converters 5-14c and 5-14d (photodiodes (PD)). The antireflector 20-14 having a moth-eye structure can amplify sensitivity attenuated by prevention of color mixing by the light absorbing members 1-14G and 1-14R.

Portions (trench structures) 8 dug into a light receiving surface (upper side in FIG. 14(b)) of the semiconductor substrate 7 are filled with the light absorbing members 1-14G and 1-14R via the metal oxide film 2, respectively. In FIG. 14(b), the light absorbing members 1-14G and 1-14R each contain tungsten (W), but may contain, for example, at least one selected from the group consisting of aluminum (Al), copper (Cu), and a carbon-based material. Since a method for manufacturing the light absorbing members 1-14G and 1-14R is similar to the method for manufacturing the light absorbing member 1-12R described above, description thereof is omitted here.

As described above, the contents described for the solid-state imaging device according to the third embodiment (example 3 of solid-state imaging device) of the present technology can be applied to the solid-state imaging device according to the first and second embodiments of the present technology described above and a solid-state imaging device according a fourth embodiment of the present technology described later unless there is a particular technical contradiction.

### 5. Fourth Embodiment (Example 4 of Solid-State Imaging Device)

A solid-state imaging device according to a fourth embodiment (example 4 of solid-state imaging device) of the present technology is a solid-state imaging device including a plurality of pixels arranged therein, in which in each of the pixels, one on-chip lens that condenses incident light and at least one photoelectric converter formed in a semiconductor substrate are provided in order from a light incident side, at least one pixel among the plurality of pixels includes the one on-chip lens and the plurality of photoelectric converters, between the plurality of photoelectric converters, a light reflecting member that reflects at least a part of light condensed by the one on-chip lens is provided, and a moth-eye structure is formed on a light receiving surface side of the semiconductor substrate above the photoelectric converter. In the solid-state imaging device according to the fourth embodiment (example 4 of solid-state imaging device) of the present technology, a trench may be formed between the plurality of photoelectric converters, a light reflecting member may be provided above the trench on a light incident side, the light reflecting member may be provided in at least a part of the trench, and moreover, the light reflecting member and an insulating film may be provided in at least a part of the trench in order from the light incident side.

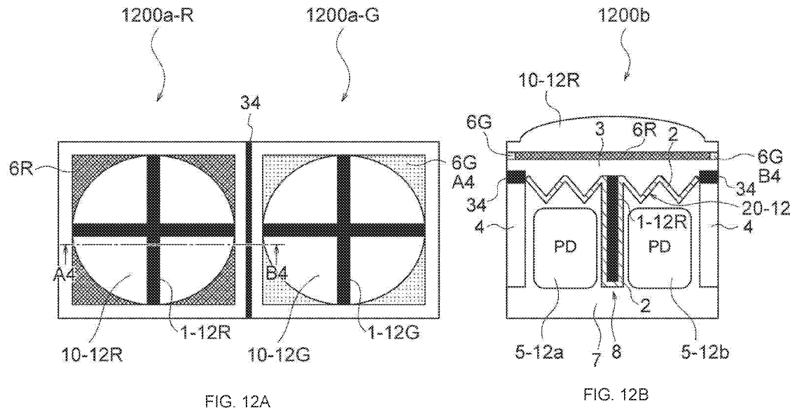

The solid-state imaging device according to the fourth embodiment of the present technology will be described with reference to FIG. 11. FIG. 11 is a diagram illustrating a configuration example of the solid-state imaging device according to the fourth embodiment of the present technology. More specifically, FIG. 11(a) is a diagram illustrating a cross-sectional configuration example for one pixel of a solid-state imaging device 1100 according to the fourth embodiment of the present technology. FIG. 11(b) is a diagram illustrating a cross-sectional configuration example of a light reflecting member 90-1 having an edge structure E that can be provided in the solid-state imaging device 1100 according to the fourth embodiment of the present technology. FIG. 11(c) is a diagram illustrating a cross-sectional configuration example of a light reflecting member 90-2 having a curved surface structure R that can be provided in the solid-state imaging device 1100 according to the fourth embodiment of the present technology. FIG. 11(d) is a diagram illustrating a cross-sectional configuration example of a light reflecting member 90-3 having a flat structure that can be provided in the solid-state imaging device 1100 according to the fourth embodiment of the present technology. FIG. 11(e) is a diagram illustrating a cross-sectional configuration example of a light reflecting member 90-4 having a flat structure that can be provided in the solid-state imaging device 1100 according to the fourth embodiment of the present technology. Note that the width of the flat structure of the light reflecting member 90-4 (the length in a left-right direction in FIG. 11(e)) is larger than the width of the flat structure of the light reflecting member 90-3 (the length in a left-right direction in FIG. 11(d)).

As illustrated in FIG. 11, the solid-state imaging device 1100 (for one pixel) includes, in order from a light incident side, an on-chip lens 10 that condenses incident light, a color filter 6R (the color filter is a red (R) color filter in FIG. 11, but is not limited to the red (R) color filter), an insulating film 3 (for example, a silicon oxide (SiO₂) film), and two photoelectric converters 5-11a and 5-11b (photodiodes (PD)) formed in a semiconductor substrate 7. An insulating film 4-2 with which the trench structure 8 is filled is provided between the photodiode 5-11a and the photodiode 5-11b. In addition, a light reflecting member 90 is formed above the trench structure 8 on a light incident side. The solid-state imaging device 1100 can be manufactured by, for example, the method for manufacturing the solid-state imaging device 800 described above.

Since incident light L5 travels in a direction of arrow S8, light L5 is reflected by the light reflecting member 90 (part Q2 in FIG. 11(a)), travels in a direction of arrow S9, and is emitted to the outside of the solid-state imaging device 1100, the incident light near a portion (central separation zone of a pixel) between the photodiode 5-11a and the photodiode 5-11b is not absorbed by the photodiode 5-11a or the photodiode 5-11b, and color mixing can be prevented. The light reflecting member 90 is not limited as long as the light reflecting member 90 contains a material having a refractive index lower than the refractive index of the insulating film 3, but contains, for example, silver (Ag) or gold (Au). In the solid-state imaging device 1100, an antireflector 20-11 having a moth-eye structure having a fine uneven structure is formed on a light receiving surface side of the semiconductor substrate 7 above the two photoelectric converters 5-11a and 5-11b (photodiodes (PD)). The antireflector 20-11 having a moth-eye structure can amplify sensitivity attenuated by prevention of color mixing by the light reflecting member 90.

As illustrated in FIG. 11(b), the light reflecting member may be a light reflecting member 90-1 having an edge structure E obtained by processing a surface of the light reflecting member, or as illustrated in FIG. 11(c), the light reflecting member may be a light reflecting member 90-2 having a curved surface structure R obtained by processing the surface of the light reflecting member. Light can be reflected by the light reflecting member 90-1 and the light reflecting member 90-2.

As illustrated in FIGS. 11(d) and 11(e), since the width of the flat structure of the light reflecting member 90-4 (the length in a left-right direction in FIG. 11(e)) is larger than the width of the flat structure of the light reflecting member 90-3 (the length in a left-right direction in FIG. 4(d)), light reflectivity can be enhanced and color mixing can be further prevented, but sensitivity may decrease in proportion to reflected light with enhanced reflectivity. Therefore, the width of the flat structure of the light reflecting member needs to be determined in consideration of a balance between color mixing prevention and sensitivity increase.

As described above, the contents described for the solid-state imaging device according to the fourth embodiment (example 4 of solid-state imaging device) of the present technology can be applied to the solid-state imaging devices according to the first to fourth embodiments of the present technology described above unless there is a particular technical contradiction.

### 6. Fifth Embodiment (Example of Electronic Apparatus)

An electronic apparatus according to a fifth embodiment of the present technology is an electronic apparatus on which any one of the solid-state imaging devices according to the first to fourth embodiments of the present technology is mounted.

### 7. Use Example of Solid-State Imaging Device to which the Present Technology is Applied

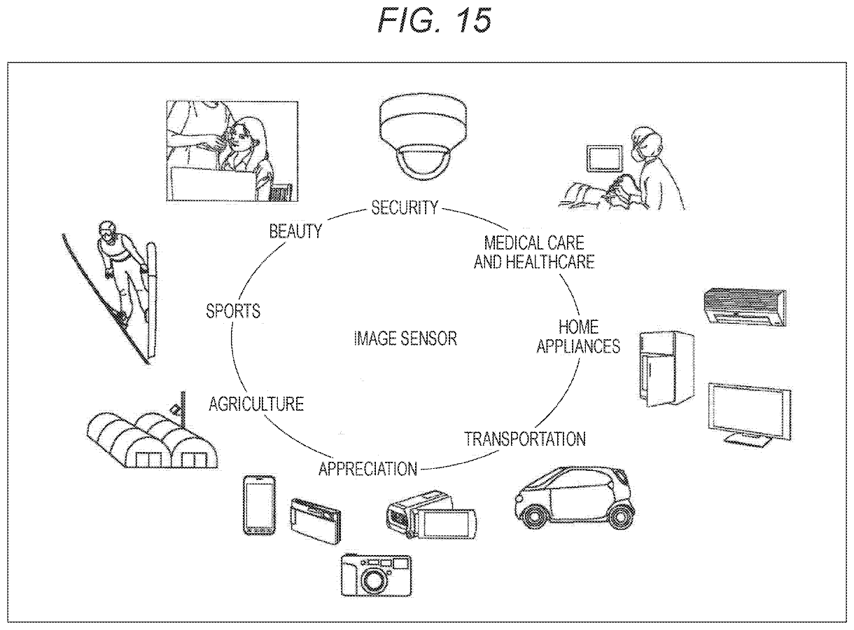

FIG. 15 is a diagram illustrating a use example of the solid-state imaging devices according to the first to fourth embodiments of the present technology as an image sensor (solid-state imaging device).

The solid-state imaging devices according to the first to fourth embodiments described above can be used, for example, in various cases of sensing light such as visible light, infrared light, ultraviolet light, or an X-ray as described below. That is, as illustrated in FIG. 15, the solid-state imaging device according to any one of the first to fourth embodiments can be used for a device used in, for example, a field of appreciation for capturing an image for appreciation, a field of transportation, a field of home appliances, a field of medical care and healthcare, a field of security, a field of beauty, a field of sports, a field of agriculture, and the like (for example, the electronic apparatus according to the fifth embodiment described above).

Specifically, in the field of appreciation, the solid-state imaging device according to any one of the first to fourth embodiments can be used, for example, for a device for capturing an image for appreciation, such as a digital camera, a smartphone, or a mobile phone with a camera function.

In the field of transportation, the solid-state imaging device according to any one of the first to fourth embodiments can be used, for example, for a device for transportation, such as a vehicle-mounted sensor for imaging the front, the back, the surrounding, the inside, or the like of an automobile for safe driving such as automatic stop, for recognition of a driver's condition, and the like, a monitoring camera for monitoring a traveling vehicle and a road, or a measuring sensor for measuring a distance between vehicles or the like.

In the field of home appliances, the solid-state imaging device according to any one of the first to fourth embodiments can be used, for example, for a device for home appliances such as a television receiver, a refrigerator, or an air conditioner for imaging a user's gesture and performing device operation according to the gesture.

In the field of medical care and healthcare, the solid-state imaging device according to any one of the first to fourth embodiments can be used, for example, for a device for medical care and healthcare, such as an endoscope or a device for performing blood vessel imaging by receiving infrared light.

In the field of security, the solid-state imaging device according to any one of the first to fourth embodiments can be used, for example, for a device for security, such as a monitoring camera for security use or a camera for person authentication.

In the field of beauty, the solid-state imaging device according to any one of the first to fourth embodiments can be used, for example, for a device for beauty, such as a skin measuring device for imaging the skin or a microscope for imaging the scalp.

In the field of sports, the solid-state imaging device according to any one of the first to fourth embodiments can be used, for example, for a device for sports, such as an action camera or a wearable camera for sports use or the like.

In the field of agriculture, the solid-state imaging device according to any one of the first to fourth embodiments can be used, for example, for a device for agriculture, such as a camera for monitoring the state of a field or a crop.

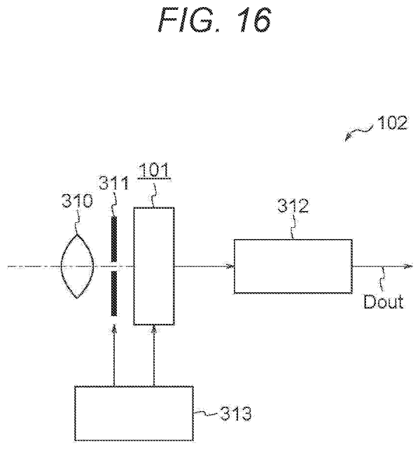

Next, a use example of the solid-state imaging devices according to the first to fourth embodiments of the present technology will be specifically described. For example, the solid-state imaging device according to any one of the first to fourth embodiments described above is used. Specifically, as a solid-state imaging device 101, the solid-state imaging device according to any one of the first to fourth embodiments can be applied to any type of electronic apparatus having an imaging function, such as a camera system including, for example, a digital still camera and a video camera, or a mobile phone having an imaging function. As an example thereof, FIG. 16 illustrates a schematic configuration of an electronic apparatus 102 (camera). The electronic apparatus 102 is, for example, a video camera capable of capturing a still image or a moving image, and includes the solid-state imaging device 101, an optical system (optical lens) 310, a shutter device 311, a drive unit 313 that drives the solid-state imaging device 101 and the shutter device 311, and a signal processing unit 312.

The optical system 310 guides image light (incident light) from a subject to a pixel unit 101a of the solid-state imaging device 101. This optical system 310 may include a plurality of optical lenses. The shutter device 311 controls a light irradiation period and a light blocking period to the solid-state imaging device 101. The drive unit 313 controls a transfer operation of the solid-state imaging device 101 and a shutter operation of the shutter device 311. The signal processing unit 312 performs various types of signal processing on a signal output from the solid-state imaging device 101. A video signal Dout after signal processing is stored in a storage medium such as a memory or is output to a monitor and the like.

### 8. Application Example to Endoscopic Surgical System

The present technology can be applied to various products. For example, the technology according to the present disclosure (present technology) may be applied to an endoscopic surgical system.

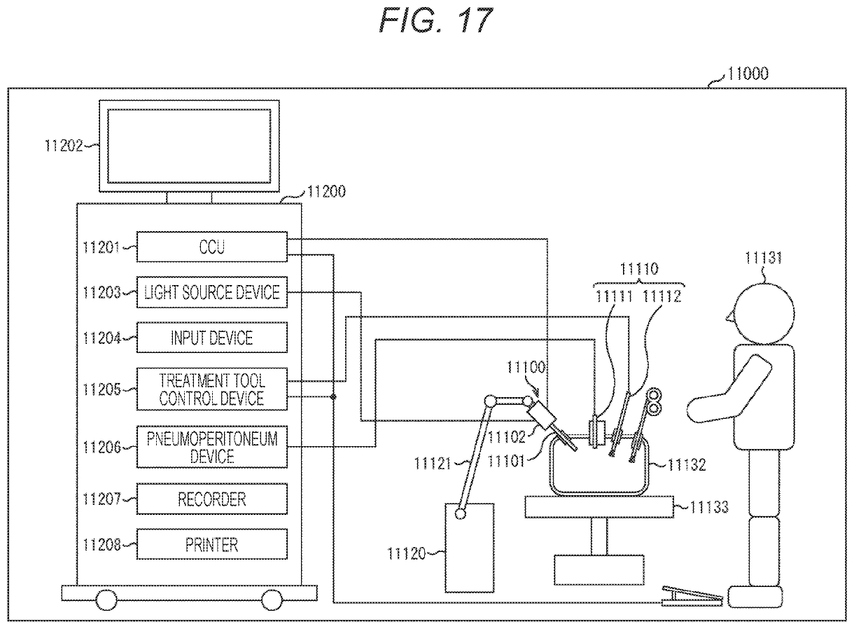

FIG. 17 is a diagram illustrating an example of a schematic configuration of an endoscopic surgical system to which the technology according to the present disclosure (present technology) can be applied.

FIG. 17 illustrates a situation in which a surgeon (physician) 11131 is performing surgery on a patient 11132 on a patient bed 11133 using an endoscopic surgical system 11000. As illustrated in the drawing, the endoscopic surgical system 11000 includes an endoscope 11100, another surgical tool 11110 such as a pneumoperitoneum tube 11111 or an energy treatment tool 11112, a support arm device 11120 for supporting the endoscope 11100, and a cart 11200 on which various devices for endoscopic surgery are mounted.

The endoscope 11100 includes a lens barrel 11101 to be inserted into a body cavity of the patient 11132 in a region of a predetermined length from a tip thereof, and a camera head 11102 connected to a proximal end of the lens barrel 11101. In the illustrated example, the endoscope 11100 configured as a so-called rigid mirror including the rigid lens barrel 11101 is illustrated, but the endoscope 11100 may be configured as a so-called flexible mirror including a flexible lens barrel.

At the tip of the lens barrel 11101, an opening into which an objective lens is fitted is provided. A light source device 11203 is connected to the endoscope 11100. Light generated by the light source device 11203 is guided to the tip of the lens barrel by a light guide extended inside the lens barrel 11101, and is emitted toward an observation target in a body cavity of the patient 11132 via the objective lens. Note that the endoscope 11100 may be a forward-viewing endoscope, an oblique-viewing endoscope, or a side-viewing endoscope.

An optical system and an imaging element are provided inside the camera head 11102. Reflected light (observation light) from an observation target is converged on the imaging element by the optical system. The observation light is photoelectrically converted by the imaging element, and an electric signal corresponding to the observation light, that is, an image signal corresponding to an observation image is generated. The image signal is transmitted as RAW data to a camera control unit (CCU) 11201.

The CCU 11201 includes a central processing unit (CPU), a graphics processing unit (GPU), and the like, and integrally controls operations of the endoscope 11100 and the display device 11202. Moreover, the CCU 11201 receives an image signal from the camera head 11102, and performs, on the image signal, various image processing for displaying an image based on the image signal, such as development processing (demosaic processing), for example.

The display device 11202 displays an image based on an image signal subjected to image processing by the CCU 11201 under the control of the CCU 11201.

The light source device 11203 includes a light source such as a light emitting diode (LED), for example, and supplies irradiation light for imaging a surgical site or the like to the endoscope 11100.

An input device 11204 is an input interface to the endoscopic surgical system 11000. A user can input various kinds of information and instructions to the endoscopic surgical system 11000 via the input device 11204. For example, the user inputs an instruction or the like to change imaging conditions (type of irradiation light, magnification, focal length, and the like) by the endoscope 11100.

A treatment tool control device 11205 controls driving of the energy treatment tool 11112 for cauterizing and cutting a tissue, sealing a blood vessel, or the like. A pneumoperitoneum device 11206 feeds a gas into a body cavity via the pneumoperitoneum tube 11111 in order to inflate the body cavity of the patient 11132 for the purpose of securing a field of view by the endoscope 11100 and securing a working space of a surgeon. A recorder 11207 is a device capable of recording various kinds of information regarding surgery. A printer 11208 is a device capable of printing various kinds of information regarding surgery in various formats such as a text, an image, and a graph.

Note that the light source device 11203 for supplying irradiation light used for imaging a surgical site to the endoscope 11100 may include an LED, a laser light source, or a white light source constituted by a combination thereof, for example. In a case where the white light source is constituted by a combination of RGB laser light sources, the output intensity and the output timing of each color (each wavelength) can be controlled with high precision, and therefore adjustment of a white balance of an imaged image can be performed by the light source device 11203. Furthermore, in this case, by irradiating an observation target with laser light from each of the RGB laser light sources in a time division manner and controlling driving of an imaging element of the camera head 11102 in synchronization with the irradiation timing, it is also possible to image an image corresponding to each of RGB in a time division manner. According to this method, a color image can be obtained without disposing a color filter in the imaging element.

Furthermore, driving of the light source device 11203 may be controlled so as to change the intensity of light output at predetermined time intervals. By controlling driving of the imaging element of the camera head 11102 in synchronization with the timing of the change of the intensity of the light to acquire an image in a time division manner and synthesizing the image, a high dynamic range image without so-called blocked up shadows or blown out highlights can be generated.

Furthermore, the light source device 11203 may be configured so as to be able to supply light in a predetermined wavelength band corresponding to special light observation. In the special light observation, for example, by irradiation with light in a narrower band than irradiation light (in other words, white light) at the time of ordinary observation using wavelength dependency of light absorption in a body tissue, a predetermined tissue such as a blood vessel of a mucosal surface layer is imaged at a high contrast, that is, so-called narrow band imaging is performed. Alternatively, in the special light observation, fluorescence observation for obtaining an image by fluorescence generated by irradiation with excitation light may be performed. In the fluorescence observation, it is possible to observe fluorescence from a body tissue (autofluorescence observation) by irradiating the body tissue with excitation light, or to obtain a fluorescent image by injecting a reagent such as indocyanine green (ICG) into a body tissue and irradiating the body tissue with excitation light corresponding to a fluorescence wavelength of the reagent, for example. The light source device 11203 can be configured so as to be able to supply narrow band light and/or excitation light corresponding to such special light observation.

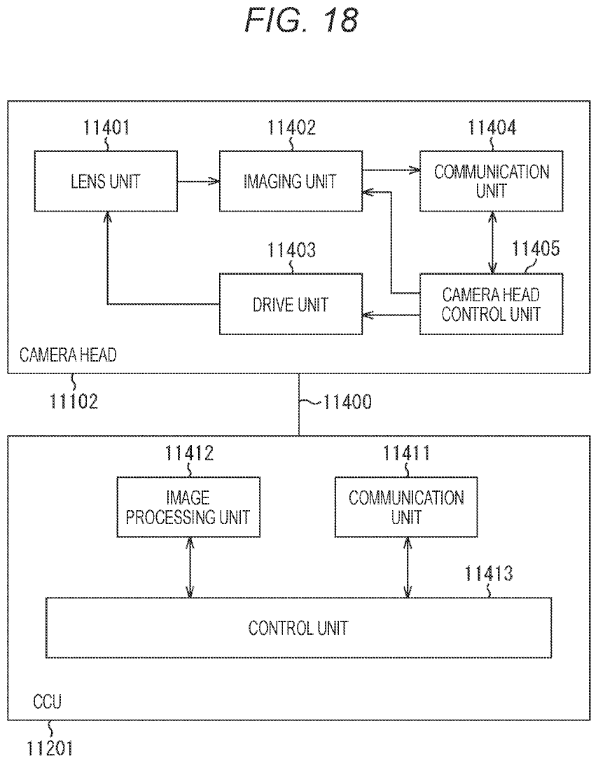

FIG. 18 is a block diagram illustrating examples of functional configurations of the camera head 11102 and the CCU 11201 illustrated in FIG. 17.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are communicably connected to each other by a transmission cable 11400.

The lens unit 11401 is an optical system provided at a connecting portion with the lens barrel 11101. Observation light taken in from a tip of the lens barrel 11101 is guided to the camera head 11102 and is incident on the lens unit 11401. The lens unit 11401 includes a combination of a plurality of lenses including a zoom lens and a focus lens.

The imaging unit 11402 includes an imaging element. The imaging unit 11402 may include one imaging element (so-called single plate type) or a plurality of imaging elements (so-called multiplate type). In a case where the imaging unit 11402 includes multiplate type imaging elements, for example, an image signal corresponding to each of RGB may be generated by each imaging element, and a color image may be obtained by synthesizing these image signals. Alternatively, the imaging unit 11402 may include a pair of imaging elements for acquiring an image signal for each of the right eye and the left eye corresponding to three-dimensional (3D) display. By performing the 3D display, the surgeon 11131 can grasp the depth of a living tissue in a surgical site more accurately. Note that in a case where the imaging unit 11402 includes multiplate type imaging elements, a plurality of lens units 11401 can be provided corresponding to the respective imaging elements.

Furthermore, the imaging unit 11402 is not necessarily provided in the camera head 11102. For example, the imaging unit 11402 may be provided just behind an objective lens inside the lens barrel 11101.

The drive unit 11403 includes an actuator, and moves a zoom lens and a focus lens of the lens unit 11401 by a predetermined distance along an optical axis under control of the camera head control unit 11405. Therefore, the magnification and the focus of an image imaged by the imaging unit 11402 can be appropriately adjusted.

The communication unit 11404 includes a communication device for transmitting and receiving various kinds of information to and from the CCU 11201. The communication unit 11404 transmits an image signal obtained from the imaging unit 11402 as RAW data to the CCU 11201 via the transmission cable 11400.

Furthermore, the communication unit 11404 receives a control signal for controlling driving of the camera head 11102 from the CCU 11201, and supplies the control signal to the camera head control unit 11405. The control signal includes information regarding imaging conditions such as information indicating designation of a frame rate of an imaged image, information indicating designation of an exposure value at the time of imaging, and/or information indicating designation of the magnification and the focus of an imaged image, for example.

Note that the imaging conditions such as the above-described frame rate, exposure value, magnification, and focus may be appropriately designated by a user, or may be automatically set by the control unit 11413 of the CCU 11201 on the basis of an acquired image signal. In the latter case, the endoscope 11100 has a so-called auto exposure (AE) function, a so-called auto focus (AF) function, and a so-called auto white balance (AWB) function.

The camera head control unit 11405 controls driving of the camera head 11102 on the basis of a control signal from the CCU 11201 received via the communication unit 11404.

The communication unit 11411 includes a communication device for transmitting and receiving various kinds of information to and from the camera head 11102. The communication unit 11411 receives an image signal transmitted from the camera head 11102 via the transmission cable 11400.

Furthermore, the communication unit 11411 transmits a control signal for controlling driving of the camera head 11102 to the camera head 11102. The image signal and the control signal can be transmitted by electric communication, optical communication, or the like.

The image processing unit 11412 performs various kinds of image processing on the image signal which is RAW data transmitted from the camera head 11102.

The control unit 11413 performs various kinds of control concerning imaging of a surgical site or the like by the endoscope 11100 and display of an imaged image obtained by imaging a surgical site or the like. For example, the control unit 11413 generates a control signal for controlling driving of the camera head 11102.

Furthermore, the control unit 11413 causes the display device 11202 to display an imaged image of a surgical site or the like on the basis of an image signal subjected to image processing by the image processing unit 11412. In this case, the control unit 11413 may recognize various objects in the imaged image using various image recognition techniques. For example, by detecting the shape, color, and the like of an edge of an object included in the imaged image, the control unit 11413 can recognize a surgical tool such as forceps, a specific living body part, bleeding, a mist at the time of using the energy treatment tool 11112, and the like. When the display device 11202 displays the imaged image, the control unit 11413 may cause the display device 11202 to superimpose and display various kinds of surgical support information on the image of the surgical site using the recognition result. The surgical support information is superimposed and displayed, and presented to the surgeon 11131. This makes it possible to reduce a burden on the surgeon 11131 and makes it possible for the surgeon 11131 to reliably perform surgery.

The transmission cable 11400 connecting the camera head 11102 to the CCU 11201 is an electric signal cable corresponding to communication of an electric signal, an optical fiber corresponding to optical communication, or a composite cable thereof.

Here, in the illustrated example, communication is performed by wire using the transmission cable 11400, but communication between the camera head 11102 and the CCU 11201 may be performed wirelessly.

An example of the endoscopic surgical system to which the technology according to the present disclosure can be applied has been described above. The technology according to the present disclosure can be applied to the endoscope 11100, (the imaging unit 11402 of) the camera head 11102, and the like among the above-described configurations. Specifically, the solid-state imaging device according to the present technology can be applied to the imaging unit 10402. By applying the technology according to the present disclosure to the endoscope 11100, (the imaging unit 11402 of) the camera head 11102, and the like, performance of the endoscope 11100, (the imaging unit 11402 of) the camera head 11102, and the like can be improved.

The endoscopic surgical system has been described as an example here. However, the technology according to the present disclosure may also be applied to, for example, a microscopic surgery system or the like.

### 9. Application Example to Mobile Body

The technology according to the present disclosure (present technology) can be applied to various products. For example, the technology according to the present disclosure may be achieved as an apparatus mounted on any type of mobile body such as an automobile, an electric vehicle, a hybrid electric vehicle, a motorcycle, a bicycle, a personal mobility, an airplane, a drone, a ship, or a robot.

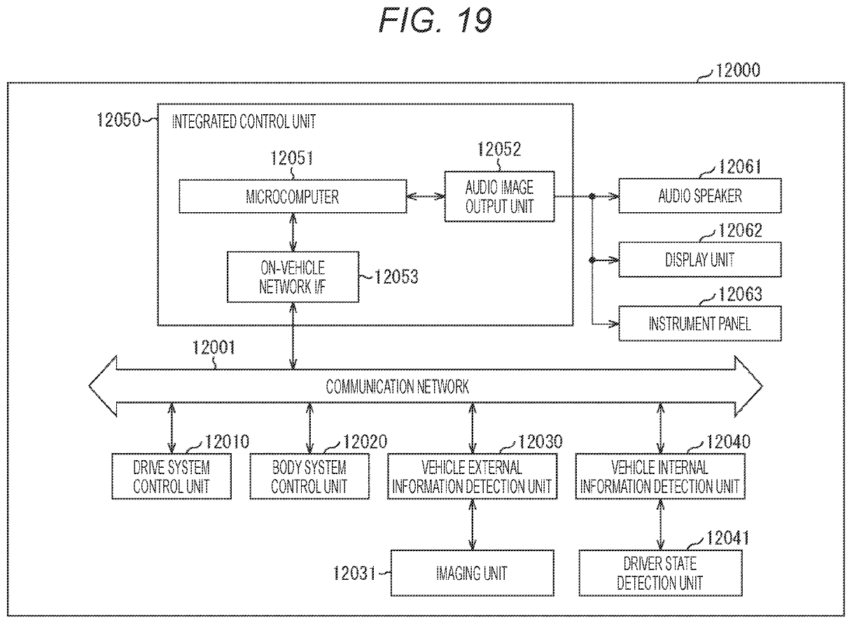

FIG. 19 is a block diagram illustrating an example of a schematic configuration of a vehicle control system which is an example of a mobile body control system to which the technology according to the present disclosure can be applied.

A vehicle control system 12000 includes a plurality of electronic control units connected to one another via a communication network 12001. In the example illustrated in FIG. 19, the vehicle control system 12000 includes a drive system control unit 12010, a body system control unit 12020, a vehicle external information detection unit 12030, a vehicle internal information detection unit 12040, and an integrated control unit 12050. Furthermore, as a functional configuration of the integrated control unit 12050, a microcomputer 12051, an audio image output unit 12052, and an on-vehicle network interface (I/F) 12053 are illustrated.

The drive system control unit 12010 controls an operation of a device related to a drive system of a vehicle according to various programs. For example, the drive system control unit 12010 functions as a control device of a driving force generating device for generating a driving force of a vehicle such as an internal combustion engine or a driving motor, a driving force transmitting mechanism for transmitting a driving force to wheels, a steering mechanism for adjusting a rudder angle of a vehicle, a braking device for generating a braking force of a vehicle, or the like.

The body system control unit 12020 controls operations of various devices mounted on a vehicle body according to various programs. For example, the body system control unit 12020 functions as a control device of a keyless entry system, a smart key system, a power window device, or various lamps such as a head lamp, a back lamp, a brake lamp, a turn indicator, and a fog lamp. In this case, to the body system control unit 12020, a radio wave transmitted from a portable device substituted for a key or signals of various switches can be input. The body system control unit 12020 receives input of the radio wave or signals and controls a door lock device, a power window device, a lamp, and the like of a vehicle.

The vehicle external information detection unit 12030 detects information outside a vehicle on which the vehicle control system 12000 is mounted. For example, to the vehicle external information detection unit 12030, an imaging unit 12031 is connected. The vehicle external information detection unit 12030 causes the imaging unit 12031 to image an image outside a vehicle and receives an imaged image. The vehicle external information detection unit 12030 may perform object detection processing or distance detection processing of a person, a car, an obstacle, a sign, a character on a road surface, or the like on the basis of the received image.

The imaging unit 12031 is a light sensor for receiving light and outputting an electric signal corresponding to the amount of light received. The imaging unit 12031 can output an electric signal as an image or output the electric signal as distance measurement information. Furthermore, the light received by the imaging unit 12031 may be visible light or invisible light such as infrared light.

The vehicle internal information detection unit 12040 detects information inside a vehicle. To the vehicle internal information detection unit 12040, for example, a driver state detection unit 12041 for detecting the state of a driver is connected. The driver state detection unit 12041 includes, for example, a camera for imaging a driver. The vehicle internal information detection unit 12040 may calculate the degree of fatigue or the degree of concentration of a driver or may determine whether or not the driver is dozing off on the basis of detection information input from the driver state detection unit 12041.

The microcomputer 12051 can calculate a control target value of a driving force generating device, a steering mechanism, or a braking device on the basis of information inside and outside a vehicle, acquired by the vehicle external information detection unit 12030 or the vehicle internal information detection unit 12040, and can output a control command to the drive system control unit 12010. For example, the microcomputer 12051 can perform cooperative control aiming at realizing a function of advanced driver assistance system (ADAS) including collision avoidance or impact mitigation of a vehicle, following travel based on inter-vehicle distance, vehicle speed maintenance travel, vehicle collision warning, vehicle lane departure warning, and the like.

Furthermore, the microcomputer 12051 can perform cooperative control aiming at, for example, automatic driving that autonomously travels without depending on driver's operation by controlling a driving force generating device, a steering mechanism, a braking device, or the like on the basis of information around a vehicle, acquired by the vehicle external information detection unit 12030 or the vehicle internal information detection unit 12040.

Furthermore, the microcomputer 12051 can output a control command to the body system control unit 12020 on the basis of vehicle external information acquired by the vehicle external information detection unit 12030. For example, the microcomputer 12051 can perform cooperative control aiming at antiglare such as switching from high beam to low beam by controlling a headlamp according to the position of a preceding vehicle or an oncoming vehicle detected by the vehicle external information detection unit 12030.

The audio image output unit 12052 transmits at least one of an audio output signal or an image output signal to an output device capable of visually or audibly notifying a passenger of a vehicle or the outside of the vehicle of information. In the example of FIG. 19, as the output device, an audio speaker 12061, a display unit 12062, and an instrument panel 12063 are illustrated. The display unit 12062 may include an on-board display and/or a head-up display, for example.

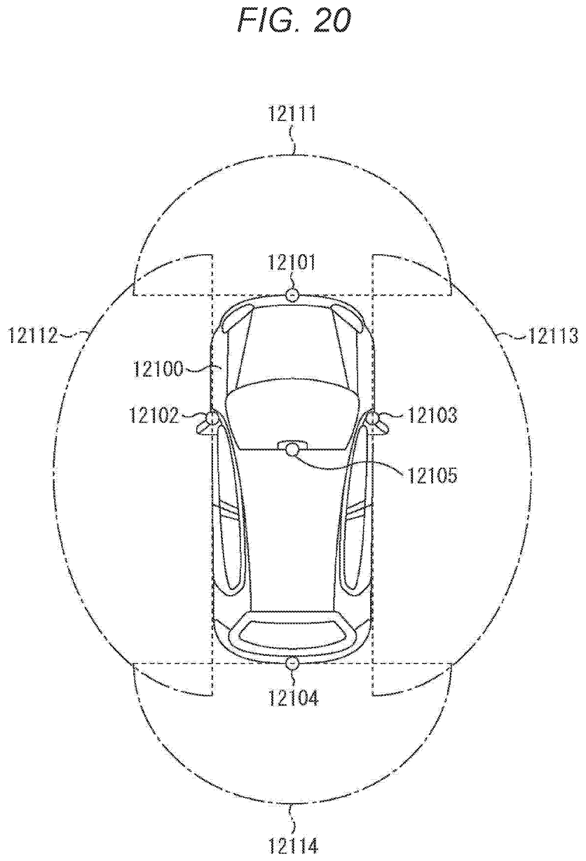

FIG. 20 is a diagram illustrating an example of an installation position of the imaging unit 12031.

In FIG. 20, the vehicle 12100 includes imaging units 12101, 12102, 12103, 12104, and 12105 as the imaging unit 12031.

The imaging units 12101, 12102, 12103, 12104, and 12105 are provided, for example, in a front nose, a side mirror, a rear bumper, and a back door of the vehicle 12100, in an upper portion of a front glass in a passenger compartment, and the like. The imaging unit 12101 provided in a front nose and the imaging unit 12105 provided in an upper portion of a front glass in a passenger compartment mainly acquire images in front of the vehicle 12100. The imaging units 12102 and 12103 provided in side mirrors mainly acquire images on sides of the vehicle 12100. The imaging unit 12104 provided in a rear bumper or a back door mainly acquires an image behind the vehicle 12100. The front images acquired by the imaging units 12101 and 12105 are mainly used for detecting a preceding vehicle, a pedestrian, an obstacle, a traffic signal, a traffic sign, a lane, or the like.

Note that FIG. 20 illustrates examples of imaging ranges of the imaging units 12101 to 12104. An imaging range 12111 indicates an imaging range of the imaging unit 12101 provided in a front nose. Imaging ranges 12112 and 12113 indicate imaging ranges of the imaging units 12102 and 12103 provided in side mirrors, respectively. An imaging range 12114 indicates an imaging range of the imaging unit 12104 provided in a rear bumper or a back door. For example, by superimposing image data imaged by the imaging units 12101 to 12104 on one another, an overhead view image of the vehicle 12100 viewed from above is obtained.

At least one of the imaging units 12101 to 12104 may have a function of acquiring distance information. For example, at least one of the imaging units 12101 to 12104 may be a stereo camera including a plurality of imaging elements, or may be an imaging element having pixels for phase difference detection.

For example, the microcomputer 12051 determines a distance to each three-dimensional object in the imaging range 12111 to 12114 and a temporal change (relative speed with respect to the vehicle 12100) of the distance on the basis of the distance information obtained from the imaging units 12101 to 12104, and can thereby particularly extract a three-dimensional object which is the nearest three-dimensional object on a traveling path of the vehicle 12100 and is traveling at a predetermined speed (for example, 0 km/h or more) in substantially the same direction as the vehicle 12100 as a preceding vehicle. Moreover, the microcomputer 12051 can set an inter-vehicle distance to be secured in advance in front of the preceding vehicle, and can perform automatic brake control (including following stop control), automatic acceleration control (including following start control), and the like. In this way, it is possible to perform cooperative control aiming at, for example, automatic driving that autonomously travels without depending on driver's operation.

For example, the microcomputer 12051 classifies three-dimensional object data related to a three-dimensional object into a two-wheeled vehicle, a regular vehicle, a large vehicle, a pedestrian, and another three-dimensional object such as a telegraph pole on the basis of the distance information obtained from the imaging units 12101 to 12104 and extracts data, and can use the extracted data for automatic avoidance of an obstacle. For example, the microcomputer 12051 identifies an obstacle around the vehicle 12100 as an obstacle that a driver of the vehicle 12100 can see and an obstacle that is difficult to see. Then, the microcomputer 12051 judges a collision risk indicating a risk of collision with each obstacle. When the collision risk is higher than a set value and there is a possibility of collision, the microcomputer 12051 can perform driving assistance for avoiding collision by outputting an alarm to a driver via the audio speaker 12061 or the display unit 12062, or performing forced deceleration or avoiding steering via the drive system control unit 12010.

At least one of the imaging units 12101 to 12104 may be an infrared camera for detecting an infrared ray. For example, the microcomputer 12051 can recognize a pedestrian by determining whether or not a pedestrian exists in imaged images of the imaging units 12101 to 12104. Such recognition of a pedestrian is performed by, for example, a procedure of extracting characteristic points in imaged images of the imaging units 12101 to 12104 as infrared cameras and a procedure of performing pattern matching processing on a series of characteristic points indicating an outline of an object and determining whether or not a pedestrian exists. If the microcomputer 12051 determines that a pedestrian exists in imaged images of the imaging units 12101 to 12104 and recognizes a pedestrian, the audio image output unit 12052 controls the display unit 12062 such that the display unit 12062 superimposes and displays a rectangular contour line for emphasis on the recognized pedestrian. Furthermore, the audio image output unit 12052 may control the display unit 12062 such that the display unit 12062 displays an icon or the like indicating a pedestrian at a desired position.

An example of the vehicle control system to which the technology according to the present disclosure (present technology) can be applied has been described above. The technology according to the present disclosure can be applied to, for example, the imaging unit 12031 among the above-described configurations. Specifically, the solid-state imaging device according to the present technology can be applied to the imaging unit 12031. By applying the technology according to the present disclosure to the imaging unit 12031, performance of the imaging unit 12031 can be improved.

Note that the present technology is not limited to the embodiments, the use examples, and the application examples described above, and various modifications can be made thereto without departing from the gist of the present technology.

Furthermore, the effects described here are merely examples, and the effects of the present technology are not limited thereto, and may include other effects.

Furthermore, the present technology can have the following configurations.

[1]

A solid-state imaging device including a plurality of pixels arranged therein, in which in each of the pixels, one on-chip lens that condenses incident light and at least one photoelectric converter formed in a semiconductor substrate are provided in order from a light incident side, at least one pixel among the plurality of pixels includes the one on-chip lens and the plurality of photoelectric converters, and between the plurality of photoelectric converters, a light absorbing member that absorbs at least a part of light condensed by the one on-chip lens is provided.

[2]

The solid-state imaging device according to [1], in which a moth-eye structure is formed on a light receiving surface side of the semiconductor substrate above the photoelectric converter.

[3]

The solid-state imaging device according to [1] or [2], in which a trench is formed between the plurality of photoelectric converters, and the light absorbing member is provided in at least a part of the trench.

[4]

The solid-state imaging device according to [1] or [2], in which a trench is formed between the plurality of photoelectric converters, and the light absorbing member and an insulating film are provided in at least a part of the trench in order from a light incident side.

[5]

The solid-state imaging device according to [1] or [2], in which a trench is formed between the plurality of photoelectric converters, and a light absorbing member is provided above the trench on a light incident side.

[6]

The solid-state imaging device according to any one of [1] to [5], in which the light absorbing member contains at least one selected from the group consisting of tungsten (W), aluminum (Al), copper (Cu), and a carbon-based material.

[7]

The solid-state imaging device according to any one of [1] to [6], in which a trench is formed between two of the pixels, and an insulating film is provided in at least a part of the trench.

[8]

A solid-state imaging device including a plurality of pixels arranged therein, in which

in each of the pixels, one on-chip lens that condenses incident light and at least one photoelectric converter formed in a semiconductor substrate are provided in order from a light incident side,

at least one pixel among the plurality of pixels includes the one on-chip lens and the plurality of photoelectric converters, and

between the plurality of photoelectric converters, a light reflecting member that reflects at least a part of light condensed by the one on-chip lens is provided.

[9]

The solid-state imaging device according to [8], in which a moth-eye structure is formed on a light receiving surface side of the semiconductor substrate above the photoelectric converter.

[10]

The solid-state imaging device according to [8] or [9], in which a trench is formed between the plurality of photoelectric converters, and a light reflecting member is provided above the trench on a light incident side.

[11]

The solid-state imaging device according to [8] or [9], in which a trench is formed between the plurality of photoelectric converters, and the light reflecting member is provided in at least a part of the trench.

[12]

The solid-state imaging device according to [8] or [9], in which a trench is formed between the plurality of photoelectric converters, and the light reflecting member and an insulating film are provided in at least a part of the trench in order from a light incident side.

[13]

The solid-state imaging device according to any one of [8] to [12], in which the light reflecting member contains gold (Au) and/or silver (Ag).

[14]

The solid-state imaging device according to any one of [8] to [13], in which a trench is formed between two of the pixels, and an insulating film is provided in at least a part of the trench.

[15]

An electronic apparatus having the solid-state imaging device according to any one of [1] to [14] mounted thereon.

[16]

An electronic apparatus having a solid-state imaging device mounted thereon, in which

the solid-state imaging device includes a plurality of pixels arranged therein,

in each of the pixels, one on-chip lens that condenses incident light and at least one photoelectric converter formed in a semiconductor substrate are provided in order from a light incident side,

at least one pixel among the plurality of pixels includes the one on-chip lens and the plurality of photoelectric converters, and

between the plurality of photoelectric converters, a light absorbing member that absorbs at least a part of light condensed by the one on-chip lens is provided.

[17]

An electronic apparatus having a solid-state imaging device mounted thereon, in which

the solid-state imaging device includes a plurality of pixels arranged therein,

in each of the pixels, one on-chip lens that condenses incident light and at least one photoelectric converter formed in a semiconductor substrate are provided in order from a light incident side,

at least one pixel among the plurality of pixels includes the one on-chip lens and the plurality of photoelectric converters, and

between the plurality of photoelectric converters, a light reflecting member that reflects at least a part of light condensed by the one on-chip lens is provided.

### REFERENCE SIGNS LIST

1 (1-1, 1-2, 1-3, 1-5G, 1-5R, 1-6G, 1-6R, 1-7G, 1-7R, 1-8, 1-9, 1-10, 1-12G, 1-12R, 1-13G, 1-14G, 1-14R) Light absorbing member
2 Metal oxide film (pinning film)
3 Insulating film
4 Insulating film (insulating film having trench structure)
5 (5-1a, 5-1b, 5-2a, 5-2b, 5-3a, 5-3b, 5-4a, 5-4b, 5-5a, 5-5b, 5-6a, 5-6b, 5-6c, 5-7a, 5-7b, 5-7c, 5-7d, 5-8a, 5-8b, 5-9a, 5-9b, 5-10a, 5-10b, 5-11a, 5-11b, 5-12a, 5-12b, 5-13a, 5-13b, 5-13c, 5-14a, 5-14b, 5-14c, 5-14d) Photoelectric converter (photodiode)
6(6G, 6R) Color filter
7 Semiconductor substrate
8 Trench
9 (9-1, 9-2, 9-3, 9-4), 90 (90-1, 90-2, 90-3, 90-4) Light reflecting member
10 (10-5G, 10-5R, 10-6G, 10-6G-1, 10-6R, 10-7G, 10-7R, 10-12G, 10-12R, 10-13G, 10-13G-1, 10-13R, 10-14G, 10-14R) On-chip lens
20 (20-8, 20-9, 20-10, 20-11, 20-11-1, 20-11-2, 20-12, 20-13, 20-14) Moth-eye structure (antireflector)
100, 200, 300, 400, 500 (500a-R, 500a-G, 500b), 600 (600a-R, 600a-G, 600b), 700 (700a-R, 700a-G, 700b), 800, 900, 1000, 1100, 1200 (1200a-R, 1200a-G, 1200b), 1300 (1300a-R, 1300a-G, 1300b), 1400 (1400a-R, 1400a-G, 1400b) Solid-state imaging device

1. A solid-state imaging device comprising a plurality of pixels arranged therein, wherein
in each of the pixels, one on-chip lens that condenses incident light and at least one photoelectric converter formed in a semiconductor substrate are provided in order from a light incident side,
at least one pixel among the plurality of pixels includes the one on-chip lens and the plurality of photoelectric converters, and
between the plurality of photoelectric converters, a light absorbing member that absorbs at least a part of light condensed by the one on-chip lens is provided.

2. The solid-state imaging device according to claim 1, wherein a moth-eye structure is formed on a light receiving surface side of the semiconductor substrate above the photoelectric converter.

3. The solid-state imaging device according to claim 1, wherein a trench is formed between the plurality of photoelectric converters, and the light absorbing member is provided in at least a part of the trench.

4. The solid-state imaging device according to claim 1, wherein a trench is formed between the plurality of photoelectric converters, and the light absorbing member and an insulating film are provided in at least a part of the trench in order from a light incident side.

5. The solid-state imaging device according to claim 1, wherein a trench is formed between the plurality of photoelectric converters, and the light absorbing member is provided above the trench on a light incident side.

6. The solid-state imaging device according to claim 1, wherein the light absorbing member contains at least one selected from the group consisting of tungsten (W), aluminum (Al), copper (Cu), and a carbon-based material.

7. The solid-state imaging device according to claim 1, wherein a trench is formed between two of the pixels, and an insulating film is provided in at least a part of the trench.

8. A solid-state imaging device comprising a plurality of pixels arranged therein, wherein
in each of the pixels, one on-chip lens that condenses incident light and at least one photoelectric converter formed in a semiconductor substrate are provided in order from a light incident side,
at least one pixel among the plurality of pixels includes the one on-chip lens and the plurality of photoelectric converters, and
between the plurality of photoelectric converters, a light reflecting member that reflects at least a part of light condensed by the one on-chip lens is provided.

9. The solid-state imaging device according to claim 8, wherein a moth-eye structure is formed on a light receiving surface side of the semiconductor substrate above the photoelectric converter.

10. The solid-state imaging device according to claim 8, wherein a trench is formed between the plurality of photoelectric converters, and a light reflecting member is provided above the trench on a light incident side.

11. The solid-state imaging device according to claim 8, wherein a trench is formed between the plurality of photoelectric converters, and the light reflecting member is provided in at least a part of the trench.

12. The solid-state imaging device according to claim 8, wherein a trench is formed between the plurality of photoelectric converters, and the light reflecting member and an insulating film are provided in at least a part of the trench in order from a light incident side.

13. The solid-state imaging device according to claim 8, wherein the light reflecting member contains gold (Au) and/or silver (Ag).

14. The solid-state imaging device according to claim 8, wherein a trench is formed between two of the pixels, and an insulating film is provided in at least a part of the trench.

15. An electronic apparatus comprising the solid-state imaging device according to claim 1 mounted thereon.

16. An electronic apparatus comprising the solid-state imaging device according to claim 8 mounted thereon.
